(19) United States
(12) Patent Application Publication
(10) Pub. No.: US 2025/0366082 A1
(43) Pub. Date: Nov. 27, 2025

(54) SEMICONDUCTOR STRUCTURE WITH REDUCED BODY LEAKAGE CURRENT AND METHOD FOR MANUFACTURING THE SAME

(71) Applicant: TAIWAN SEMICONDUCTOR MANUFACTURING COMPANY, LTD., Hsinchu (TW)

(72) Inventors: Po-Hsien CHENG, Hsinchu (TW); I-Hsuan LO, Hsinchu (TW); Keng-Chu LIN, Hsinchu (TW); Hao-Heng LIU, Hsinchu (TW); Tai-Chun HUANG, Hsinchu (TW); Tze-Liang LEE, Hsinchu (TW)

(73) Assignee: TAIWAN SEMICONDUCTOR MANUFACTURING COMPANY, LTD., Hsinchu (TW)

(21) Appl. No.: 18/669,948

(22) Filed: May 21, 2024

(51) Int. Cl. H01L 29/06; H01L 21/762; H01L 21/764; H01L 27/02; H01L 29/423; H01L 29/66; H01L 29/775; H01L 29/786

(52) U.S. Cl. CPC H10D 62/102; H01L 21/76224; H01L 21/764; H10D 30/6713; H10D 64/017; H10D 89/00; H10D 30/014; H10D 30/43; H10D 30/6735; H10D 30/6757; H10D 62/121

(57) ABSTRACT

A method for manufacturing a semiconductor structure includes: forming a fin structure on a substrate; forming two trench isolations on the substrate; forming dummy structures over the fin structure and the two trench isolations so that the fin structure has exposed portions which are exposed from the dummy structures, each of the dummy structures including a dummy gate; forming source/drain portions respectively in the exposed portions of the fin structure; forming a trench which penetrates through the dummy gate of a selected one of the dummy structures and through the fin structure to terminate at the substrate; and forming an isolation structure in the trench, the isolation structure including an upper portion and a lower portion which extends from the upper portion into the substrate, the upper portion and the lower portion being made of different materials, an atomic percentage of nitrogen in the lower portion being less than 1%.

### BACKGROUND

Nowadays, integrated circuits (ICs) are widely used in consumer electronics products and automotive electronics products. Transistors are key active components in modern ICs. In order to manufacture electronics products with relatively low power consumption, long service lifetime, high computing speed, and so on, various approaches are being continuously developed for optimizing each of the transistors in the ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 22 illustrate schematic views of intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

In advanced technology nodes of semiconductor fabrication, a CPODE (continuous polysilicon on oxide definition edge) structure is formed to electrically isolate two adjacent transistors which are located on the same fin. In a common practice, the entire CPODE structure is made of a silicon nitride-based material and is configured to penetrate the fin to terminate at a substrate beneath the fin. It should be noted that, during formation of the silicon nitride-based CPODE structure by atomic layer deposition, the silicon nitride-based CPODE structure is inevitably formed with positively charged defect centers, which may induce negative charges in the fin and the substrate, and thus, even if the transistors are in an off state, a body leakage current may flow from one of the transistors to an adjacent one of the transistors through the negative charges induced in the fin and the substrate.

The present disclosure is directed to methods for manufacturing a semiconductor structure which includes multiple semiconductor devices disposed on each fin, and an isolation structure disposed to separate two adjacent ones of the semiconductor devices disposed on the same fin. With the provision of the isolation structure, negative charges are less likely to be induced in each fin and a substrate beneath the each fin, and thus the body leakage current resulting from the negative charges may be mitigated. Each of the semiconductor devices may be configured as a fin-type field-effect transistor (FinFET) structure, a gate-all-around field-effect transistor (GAAFET) structure, a complementary field-effect transistor (CFET) structure which includes a lower GAAFET and an upper GAAFET sequentially formed over a substrate, a fork-sheet structure which includes two GAAFETs spaced part from each other through a wall portion which is formed on an trench isolation, or other suitable three-dimensional structures. The semiconductor devices may function as memory devices, logic devices, or power devices.

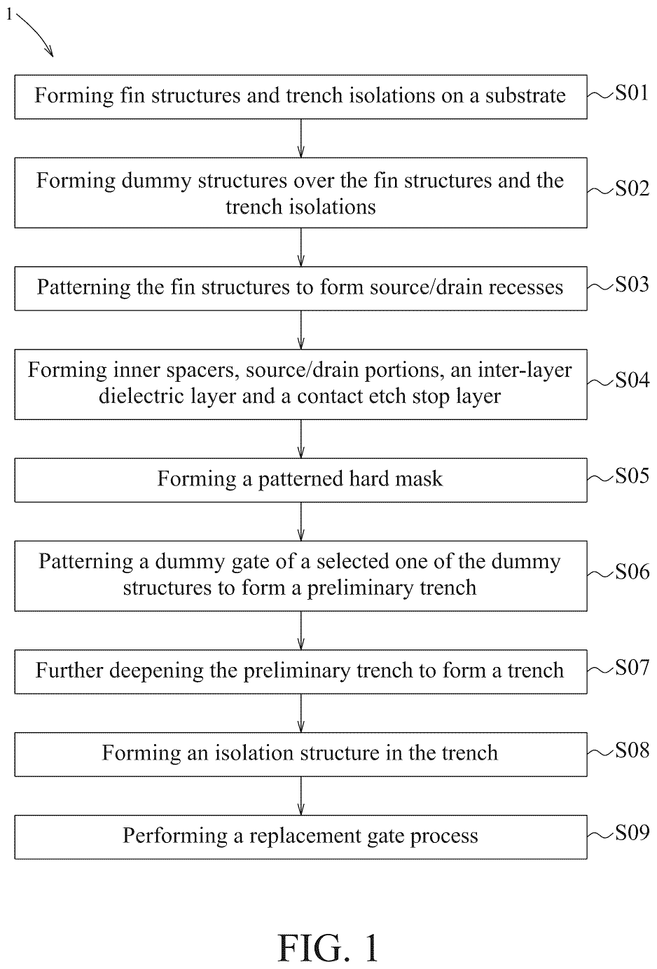

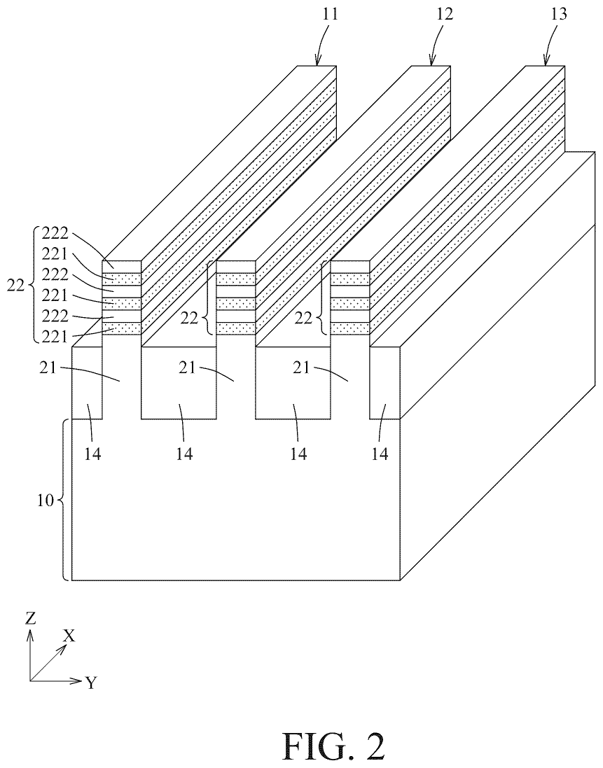

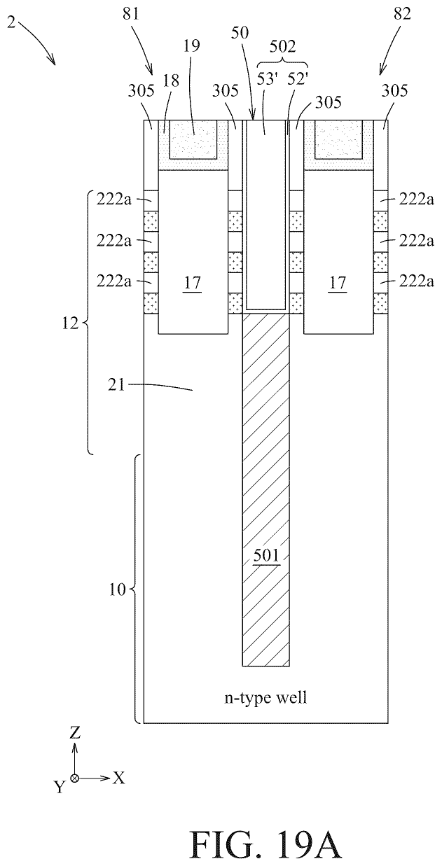

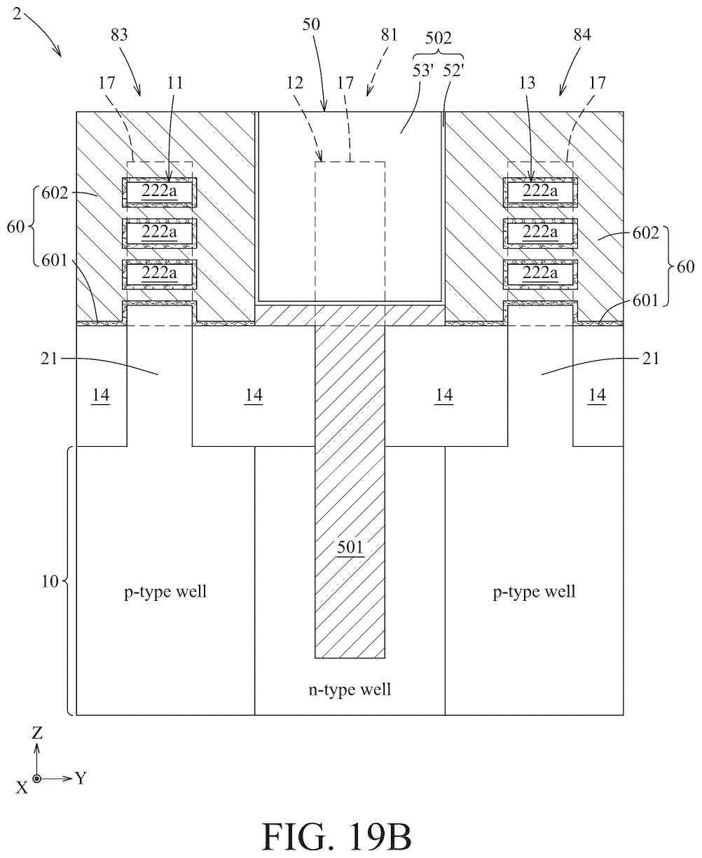

FIG. 1 is a flow diagram illustrating a method 1 for manufacturing a semiconductor structure (for example, but not limited to, a semiconductor structure 2 shown in FIGS. 19A and 19B) in accordance with some embodiments. The semiconductor structure 2 shown in FIGS. 19A and 19B is configured as a GAAFET structure, but is not limited thereto. The method 1 may include steps S01 to S09. FIGS. 2 to 22 illustrate schematic views of intermediate stages of the method 1 in accordance with some embodiments.

Referring to FIG. 1 and the example illustrated in FIG. 2, the method 1 begins at step S01, where fin structures 11, 12, 13 are formed on a substrate 10, and then trench isolations 14 are formed on the substrate 10 to alternate with the fin structures 11, 12, 13.

In some embodiments, the substrate 10 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 10 may be a bulk semiconductor substrate, for example, but not limited to, a bulk substrate of silicon, germanium, silicon germanium, or other suitable semiconductor materials (such as the examples described earlier in the same paragraph). In some embodiments, the substrate 10 may be formed with an n-type well having an n-type conductivity and a p-type well having a p-type conductivity. Each of the n-type well and the p-type well may be formed by introducing an n-type impurity or a p-type impurity into the substrate 10 by an implantation processes. In some embodiments, the n-type impurity may include phosphorous (P, ³¹P), arsenic (As), antimony (Sb), or combinations thereof. In some embodiments, the p-type impurities may include boron or boron compound (for example, B, ¹¹B, BF₂), aluminum (Al), indium (In), gallium (Ga), or combinations thereof. In some other embodiments not shown herein, the substrate 10 may be configured as a semiconductor-on-insulator substrate. Other suitable materials and configurations for the substrate 10 are within the contemplated scope of the present disclosure.

The fin structures 11, 12, 13 are elongated in an X direction and spaced apart from each other in a Y direction transverse to the X direction, and each includes a fin 21 and a stack 22 disposed on the fin 21. In some embodiments, the fin 21 may be implanted with a p-type impurity to serve as a p-type well, or may be implanted with an n-type impurity to serve as an n-type well. The examples of the p-type impurity and the n-type impurity are similar to those as described in the previous paragraph.

Each of the stacks 22 includes first layers 221 and second layers 222 disposed to alternate with the first layers 221 in a Z direction transverse the X and Y direction. In some embodiments, the X, Y and Z directions are perpendicular to each other. In some embodiments, an uppermost one of the second layers 222 is disposed over an uppermost one of the first layers 221 opposite to the substrate 10. In some embodiments, a lowermost one of the second layers 222 is spaced apart from the fin 21 by a lowermost one of the first layers 221. Each of the first layers 221 is made of a first semiconductor material, and each of the second layers 222 is made of a second semiconductor material that is different from the first semiconductor material, so that the first layers 221 may be selectively removed with the second layers 222 being substantially intact due to different etching selectivity ratios. Possible semiconductor materials suitable for forming the first and second layers 221, 222 are similar to those for forming the substrate 10, and thus the details thereof are omitted for the sake of brevity. In some embodiments, the first layers 221 are made of silicon germanium, and the second layers 222 are made of silicon. Other materials suitable for the first layers 221 and the second layers 222 are within the contemplated scope of the present disclosure.

In some embodiments, formation of the fin structures 11, 12, 13 may include (i) forming a lamination structure (not shown) on a starting substrate (not shown) by chemical vapor deposition (CVD), atomic layer deposition (ALD), an epitaxial growth process (such as molecular-beam epitaxy (MBE), selective area epitaxy (SAE), etc.), or other suitable deposition techniques, and (ii) patterning the lamination structure and the starting substrate using a photolithography process followed by an etching process. As a result, the lamination structure is patterned into the stacks 22 of the fin structures 11, 12, 13 each having a predetermined dimension in the Y direction, and the starting substrate is patterned into the substrate 10 and the fins 21 of the fin structures 11, 12, 13.

In some embodiments, the trench isolations 14 may each be a shallow trench isolation (STI), a deep trench isolation (DTI), or other suitable structures. In some embodiments, the trench isolations 14 may include silicon oxide, silicon nitride, silicon oxynitride, other low-k dielectric materials, or combinations thereof. Other insulating materials suitable for the trench isolations 14 are within the contemplated scope of the present disclosure.

In some embodiments, formation of the trench isolations 14 may include (i) forming an isolation layer over the substrate 10 and the fin structures 11, 12, 13 followed by a planarization process, for example, but not limited to, chemical mechanism polishing (CMP), to form isolation regions (not shown), and (ii) recessing the isolation regions such that the isolation regions are respectively formed into the trench isolations 14.

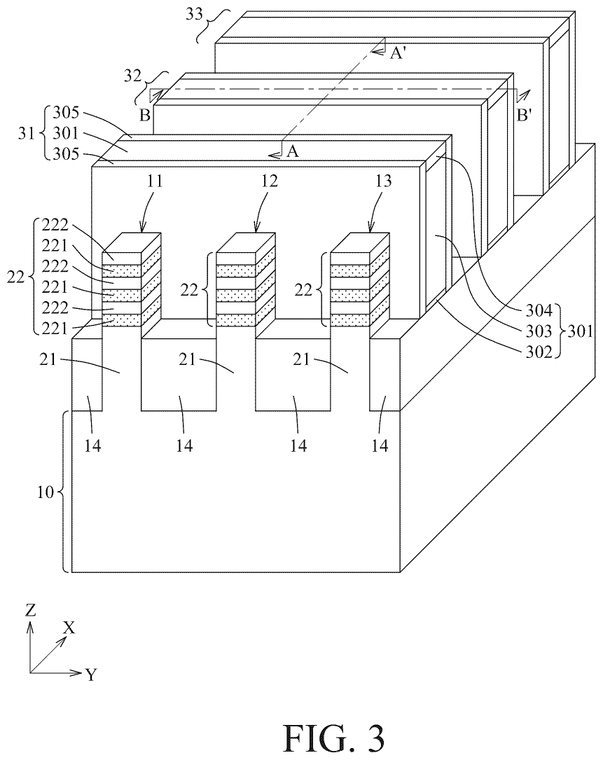

Referring to FIG. 1 and the example illustrated in FIG. 3, the method 1 proceeds to step S02, where dummy structures 31, 32, 33 are formed. FIG. 3 is a schematic perspective view similar to that of FIG. 2, but illustrating the structure after step S02.

The dummy structures 31, 32, 33 are spaced apart from each other in the X direction. Each of the dummy structures 31, 32, 33 is elongated in the Y direction and is formed over the fin structures 11, 12, 13 and the trench isolations 14, so that each of the fin structures 11, 12, 13 has exposed portions which are exposed from the dummy structures 31, 32, 33 and which are disposed to alternate with the dummy structures 31, 32, 33.

Each of the dummy structures 31, 32, 33 includes a main portion 301, and two spacers 305 disposed at two opposite sides of the main portion 301 in the X direction.

The main portion 301 includes a dummy dielectric 302 disposed over the fin structures 11, 12, 13 and the trench isolations 14, a dummy gate 303 disposed on the dummy dielectric 302, and a hard mask 304 disposed on the dummy gate 303. In some embodiments, the dummy dielectric 302 may include silicon oxide, silicon nitride, silicon oxynitride, high dielectric constant (k) materials, other suitable dielectric materials, or combinations thereof. In some embodiments, the dummy gate 303 may include polycrystalline silicon, single crystalline silicon, amorphous silicon, or combinations thereof. In some embodiments, the hard mask 304 may include silicon nitride, silicon oxide, silicon oxynitride, or combinations thereof. Other materials suitable for the main portion 301 are within the contemplated scope of the present disclosure. In some embodiments, formation of the main portion 301 may include (i) sequentially forming a first dummy layer (not shown) for forming the dummy dielectric 302 and a second dummy layer (not shown) for forming the dummy gate 303 over the fin structures 11, 12, 13 and the trench isolations 14 by CVD, ALD, physical vapor deposition (PVD), or other suitable deposition techniques, (ii) performing a planarization process (e.g., chemical mechanical polishing) to obtain a planar upper surface of the second dummy layer, (iii) forming a third dummy layer (not shown) for forming the hard mask 304 on the planarized second dummy layer, and (iv) patterning the first dummy layer, the planarized second dummy layer and the third dummy layer using a photolithography process followed by an etching process, thereby obtaining the main portion 301.

In some embodiments, the spacers 305 may be a single layer structure or a multiple layer structure, and may include, for example, but not limited to, a silicon oxide (e.g., SiO₂) based dielectric material, a silicon nitride (e.g., Si₃N₄) based dielectric material, a carbon-doped silicon oxide material, a nitride-doped silicon oxide material, a porous oxide material, other suitable materials, or combinations thereof. In some embodiments, formation of the spacers 305 includes depositing material(s) of the spacers 305 to cover the main portion 301 and the exposed portions of the fin structures 11, 12, 13 and the isolation trenches 14 by CVD, ALD, PVD, or other suitable deposition techniques, and performing an anisotropic etching process on the material(s) of the spacers 305 to expose upper surfaces of the main portion 301 and the exposed portions of the fin structures 11, 12, 13 and the isolation trenches 14 such that portions of the material(s) of the spacers 305 remain at side surfaces of the main portion 301, thereby obtaining the spacers 305. In some embodiments, during formation of the spacers 305, the material(s) of the spacers 305 is also formed into multi-pairs of fin sidewalls (not shown). Each pair of the fin sidewalls are formed at two opposite sides of a respective one of the exposed portions of each of the fin structures 11, 12, 13 in the Y direction.

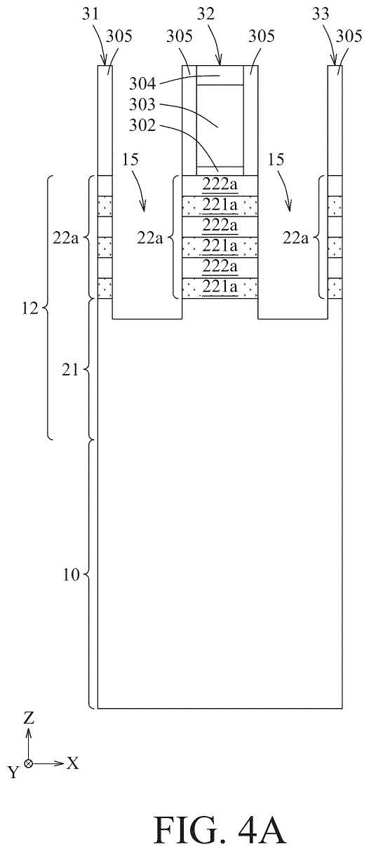

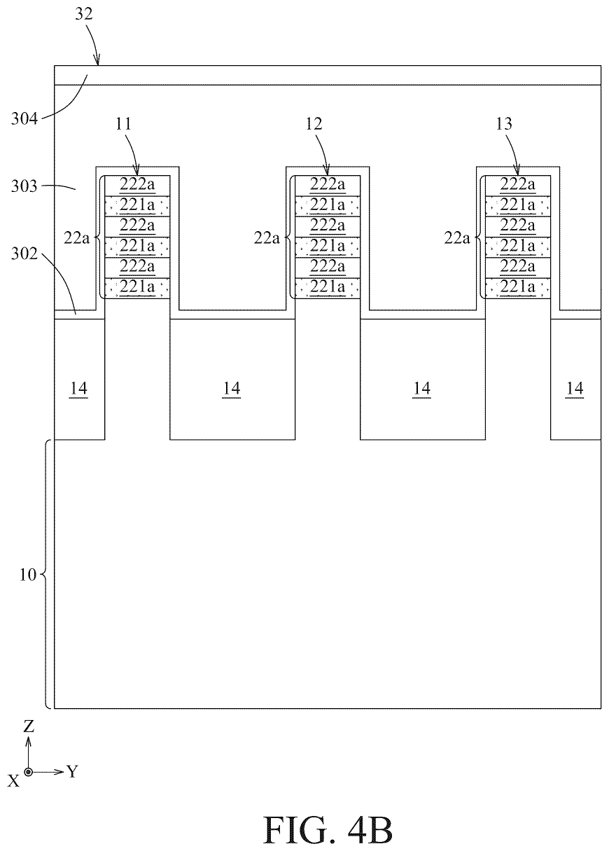

Referring to FIG. 1 and the examples illustrated in FIGS. 4A and 4B, the method 1 proceeds to step S03, where the exposed portions of each of the fin structures 11, 12, 13 (see FIG. 3) are patterned to form source/drain recesses 15, respectively, by an etching technique (for example, but not limited to, dry etching, wet etching, or a combination thereof). FIGS. 4A and 4B are schematic sectional views respectively taken along line A-A′ and line B-B′ of FIG. 3, but illustrating the structures after step S03.

In step S03, the stack 22 in each of the fin structures 11, 12, 13 (see FIG. 3) is patterned into stacking portions 22a which are respectively located beneath the dummy structures 31, 32, 33, and thus portions of the fin 21 are respectively exposed from the source/drain recesses 15. In some embodiments, the exposed portions of the fin 21 are further etched to deepen the source/drain recesses 15. The stacking portions 22a are disposed to alternate with the source/drain recesses 15 in the X direction. Each of the stacking portions 22a includes first films 221a which are respectively formed from the first layers 221, and second films 222a which are respectively formed from the second layers 222.

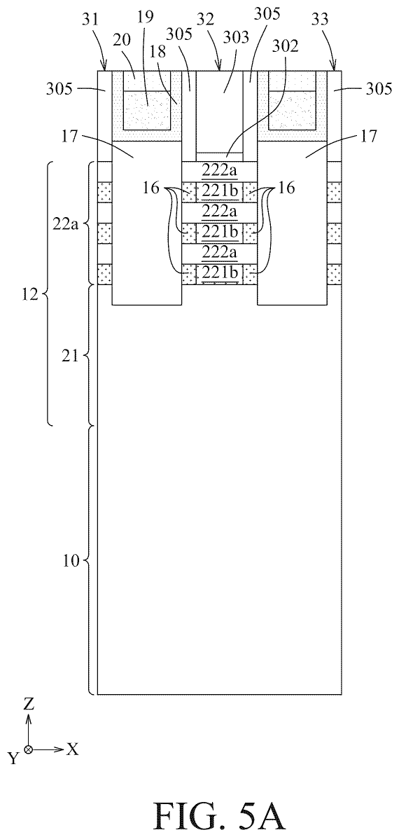

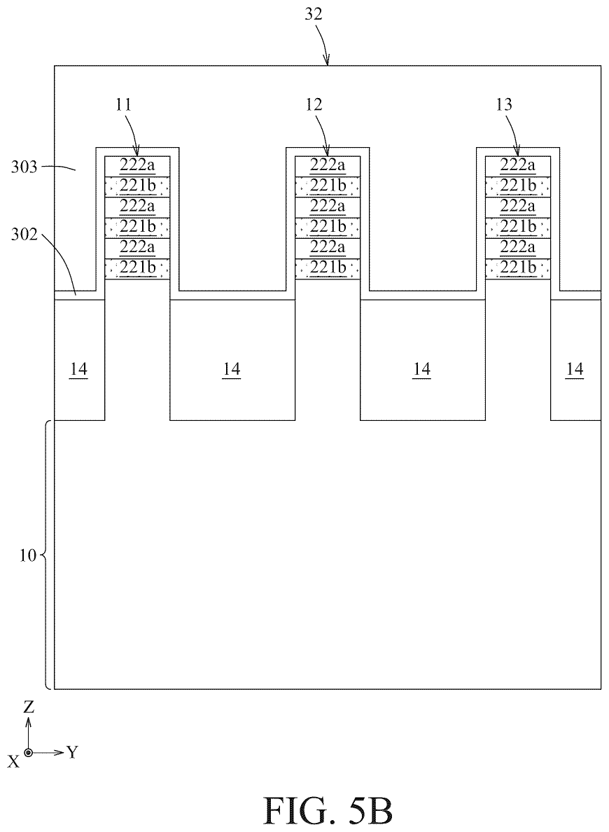

Referring to FIG. 1 and the examples illustrated in FIGS. 5A and 5B, the method 1 proceeds to step S04, where inner spacers 16 and source/drain portions 17 are formed in the fin structures 11, 12, 13. Then, a contact etch stop layer (CESL) 18, an inter-layer dielectric (ILD) layer 19 and a hard mask 20 are formed on the source/drain portions 17. FIGS. 5A and 5B are schematic sectional views respectively similar to those of FIGS. 4A and 4B, but illustrating the structures after step S04.

In some embodiments, step S04 may include multiple sub-steps as described in the following.

Before step S04, each of the first films 221a in the stacking portions 22a (see FIG. 4A) has two end portions respectively exposed from two corresponding adjacent ones of the source/drain recesses 15. In step S04, firstly, the end portions of the first films 221a are etched through the corresponding adjacent source/drain recesses 15 by an etching process to form recesses (not shown), respectively, while keeping the second films 222a substantially intact. Then, the inner spacers 16 are respectively formed in the recesses by depositing a low-k dielectric material of inner spacers 16 to cover each of the etched first films 221b and fill the recesses by CVD, ALD, PVD, or other suitable deposition techniques, and then removing excess portions of the low-k dielectric material by an anisotropic etching process, thereby obtaining the inner spacers 16. Each pair of the inner spacers 16 are respectively formed at two opposite sides of a respective one of the etched first films 221b. In some embodiments, the inner spacers 16 may include silicon oxide, silicon oxycarbide, silicon oxynitride, silicon oxycarbonitride, air gap, other suitable low-k dielectric materials, or combinations thereof.

After formation of the inner spacers 16, the source/drain portions 17 are respectively formed in the source/drain recesses 15 (see FIG. 4A). Each of the source/drain portions 17 may include single crystalline silicon, single crystalline silicon germanium alloy, single crystalline silicon carbon alloy, single crystalline silicon carbon germanium alloy, polycrystalline silicon, polycrystalline silicon germanium, polycrystalline silicon carbon alloy, polycrystalline silicon carbon germanium alloy, or other suitable materials. The source/drain portions 17 may each be doped with an n-type dopant so as to function as a source or a drain of an n-MOSFET, or may be doped with a p-type dopant so as to function as a source or a drain of a p-MOSFET. The n-type dopant may be, for example, but not limited to, phosphorous (P, ³¹P), arsenic (As), antimony (Sb), other suitable materials, or combinations thereof. The p-type dopant may be, for example, but not limited to, boron or boron compound (for example, B, ¹¹B, BF₂), aluminum (Al), gallium (Ga), indium (In), other suitable p-type dopants, or combinations thereof. In some embodiments, formation of the source/drain portions 17 may include forming epitaxial regions respectively in the source/drain recesses 15 by an epitaxial growth process (such as molecular-beam epitaxy (MBE), selective area epitaxy (SAE), etc.), or other suitable deposition techniques, followed by an implantation process for introducing the n-type dopant or the p-type dopant into the epitaxial regions. In some alternative embodiments, the implantation process may be omitted, and the n-type dopant or the p-type dopant may be in-situ doped in the epitaxial regions during the epitaxial growth process.

In some embodiments not shown herein, after formation of the inner spacers 16 and before formation of the source/drain portions 17, an etching process may be performed to reduce a dimension of the second films 222a in the X direction while keeping the dummy structures 31, 32, 33 and the inner spacers 16 intact.

After formation of the source/drain portions 17, a first layer (not shown) for forming the CESL 18 and a second layer (not shown) for forming the ILD layer 19 are sequentially formed on the source/drain portions 17 and the dummy structures 31, 32, 33 using CVD, PVD, ALD or other possible processes, followed by a planarization process (e.g., CMP) to expose the dummy gate 303 of each of the dummy structures 31, 32, 33. The first layer is formed into the CESL 18. The second layer is further etched back to have a reduced height in the Z direction by an etching process, thereby obtaining the ILD layer 19. During etching back the second layer, the first layer, and the spacers 305 and the dummy gate 303 in each of the dummy structures 31, 32, 33 are substantially intact due to the different etching selectivity ratios. Afterwards, the hard mask 20 is formed on the ILD layer 19 using CVD, PVD, ALD or other possible processes, followed by a planarization process (e.g., CMP) to expose the dummy gate 303 of each of the dummy structures 31, 32, 33.

In some embodiments, the ILD layer 19 is disposed on the source/drain portions 17, and may include silicon oxide, doped silicon oxide (e.g., phospho-silicate glass (PSG), boro-phospho-silicate glass (BPSG), fluoro-silicate glass (FSG), carbon-doped silicon oxide (SiCOH)), other suitable low-k dielectric materials, or combinations thereof. The CESL 18 is disposed to separate the ILD layer 19 from the source/drain portions 17 and the spacers 305, and may include silicon nitride, silicon oxynitride, silicon carbonnitride, or other suitable dielectric materials that are different from the material of the ILD layer 19. In some embodiments not shown herein, the CESL 18 may be omitted. In some embodiments, the hard mask 20 is disposed on the ILD layer 18, and is made of a material different from that of ILD layer 18. In some embodiments, the material of the hard mask 20 may be the same as or different from that of the CESL 18. In some embodiments, the hard mask 20 includes silicon nitride, silicon carbide, silicon oxycarbide, silicon oxynitride, silicon carbonitride, silicon oxycarbonitride, metal oxide (e.g., aluminum oxide, hafnium oxide, zirconium oxide, aluminum nitride, titanium nitride), or combinations thereof.

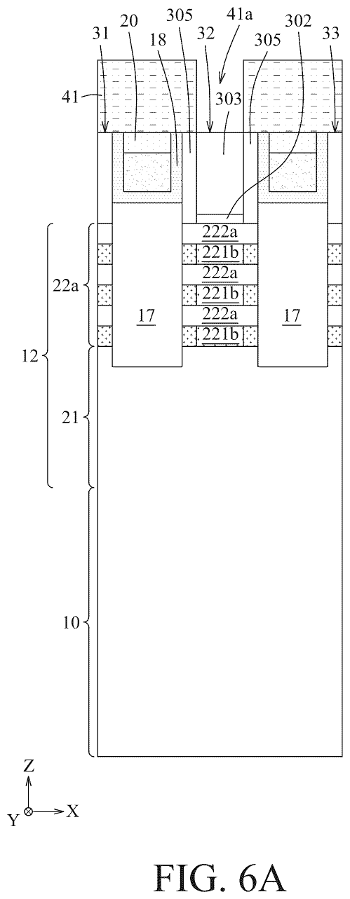

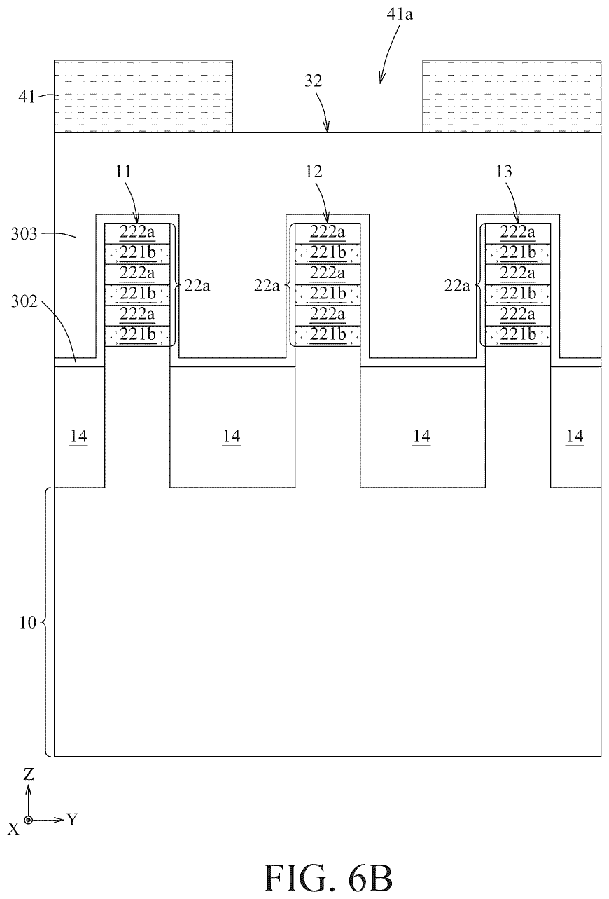

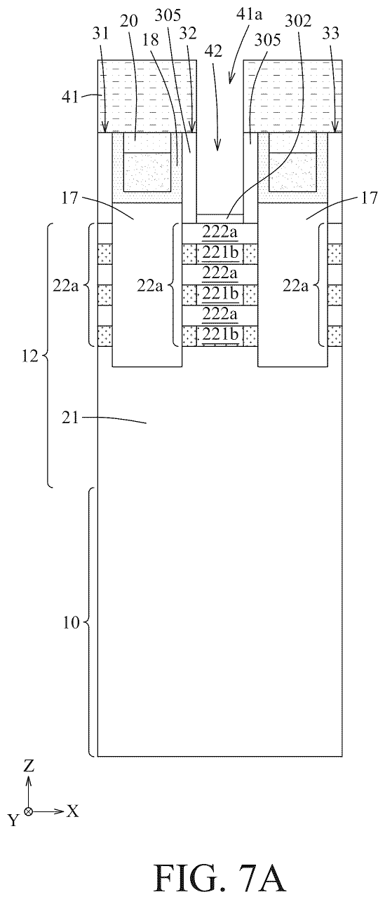

Referring to FIG. 1 and the examples illustrated in FIGS. 6A and 6B, the method 1 proceeds to step S05, where a patterned hard mask 41 is formed on the structure shown in FIGS. 5A and 5B, and has an opening 41a to expose a portion of the dummy structure 32. FIGS. 6A and 6B are schematic sectional views respectively similar to those of FIGS. 5A and 5B, but illustrating the structures after step S05.

In some embodiments, as shown in FIG. 6A, a portion of the dummy gate 303 of the dummy structure 32 is exposed from the opening 41a, whereas the spacers 305 of the dummy structure 32 is protected by the patterned hard mask 41. The dummy structures 31, 33 (see also FIG. 3), the hard mask 20 and the CESL 18 are also protected by the patterned hard mask 41 to prevent from being etched in subsequent etching processes. In some embodiments shown in FIG. 6B, the opening 41a is elongated in the Y direction so as to be located in a position above the fin structure 12. In some embodiments not shown herein, the opening 41a may be further elongated in the Y direction so as to permit the opening 41a to be in a position above both of the fin structures 11, 12. In some embodiments, possible materials for the patterned hard mask 41 are similar to those for the hard mask 20. In some embodiments, the patterned hard mask 41 is made of silicon nitride. In some embodiments, formation of the patterned hard mask 41 may include forming a hard mask layer (not shown) to cover the dummy structures 31, 32, 33, the hard mask 20 and the CESL 18 using CVD, PVD, ALD, or other possible deposition techniques, and patterning the hard mask layer by a photolithography process and an etching process following the photolithography process to form the opening 41a therein.

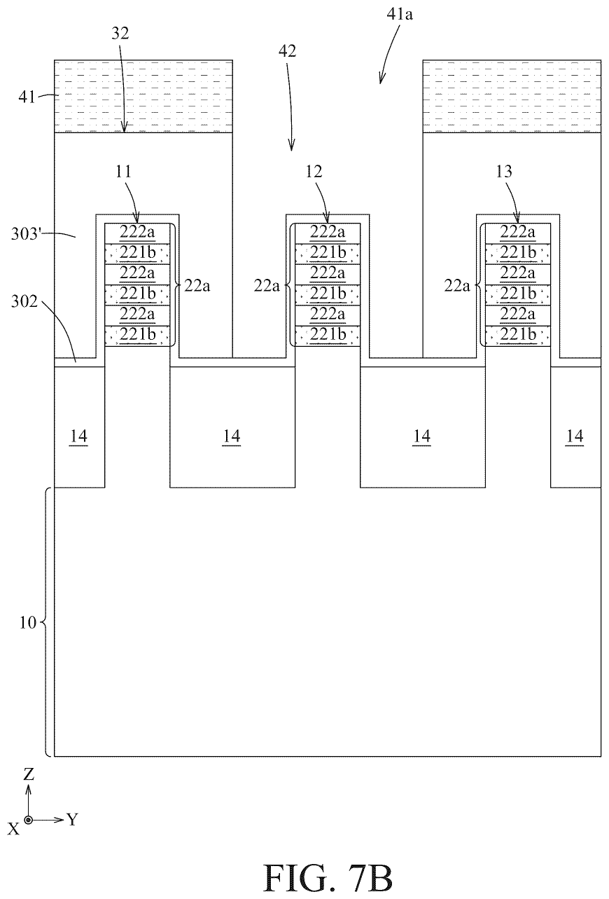

Referring to FIG. 1 and the examples illustrated in FIGS. 7A to 7B, the method 1 proceeds to step S06, where the dummy gate 303 of the dummy structure 32 (see FIGS. 6A and 6B) is patterned through the opening 41a by an etching process to from a preliminary trench 42 between the spacers 305 of the dummy structure 32. FIGS. 7A and 7B are schematic sectional views respectively similar to those of FIGS. 6A and 6B, but illustrating the structures after step S06. After step S06, a portion of the dummy dielectric 302 of the dummy structure 32 is exposed from the preliminary trench 42.

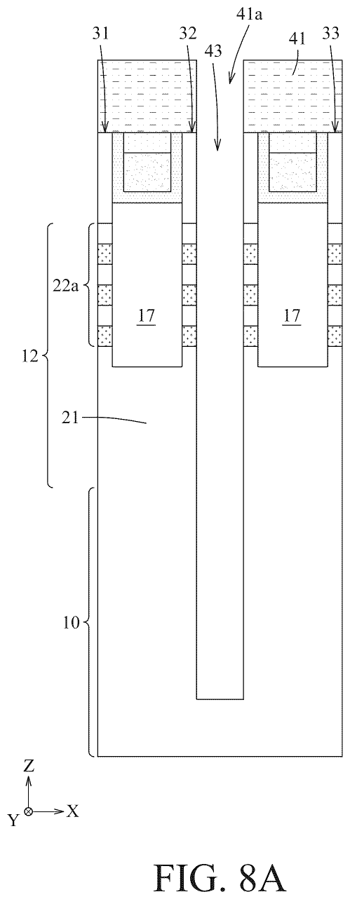

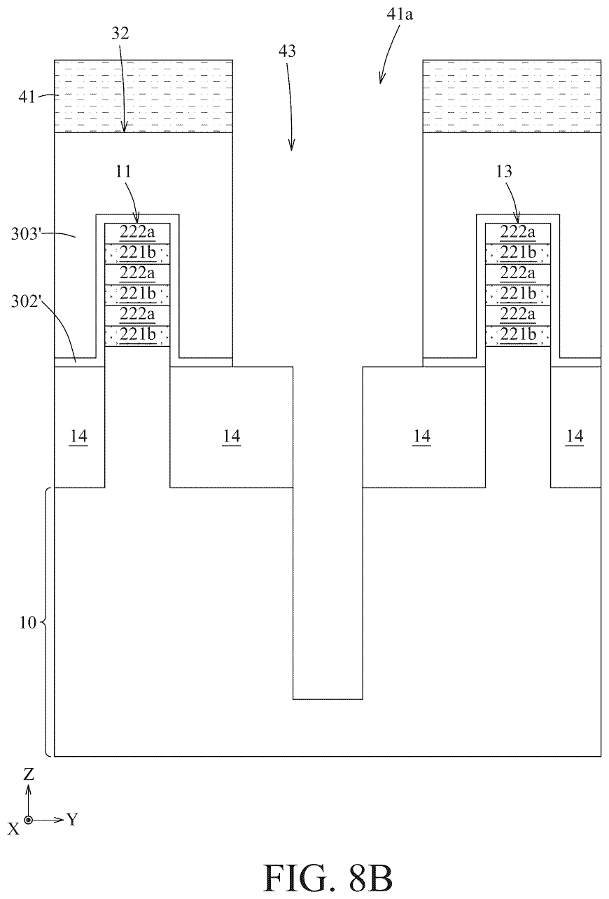

Referring to FIG. 1 and the examples illustrated in FIGS. 8A to 8B, the method 1 proceeds to step S07, where the dummy dielectric 302 of the dummy structure 32, the fin structure 12 and the substrate 10 are patterned by an etching process to further deepen the preliminary trench 42 (see FIGS. 7A and 7B) to form a trench 43. FIGS. 8A and 8B are schematic sectional views respectively similar to those of FIGS. 7A and 7B, but illustrating the structures after step S07.

Referring to FIGS. 6A, 6B, 8A, and 8B, the trench 43 penetrates the dummy gate 303 of the dummy structure 32, a middle one of the stacking portions 22a of the fin structure 12 and the fin 21 of the fin structure 12 to terminate at the substrate 10. Two of the insulating portions 14 adjacent to the trench 43 in the Y direction are substantially intact. In some embodiments, the trench 43 has a relatively high aspect ratio (i.e., a ratio of a depth to a width thereof).

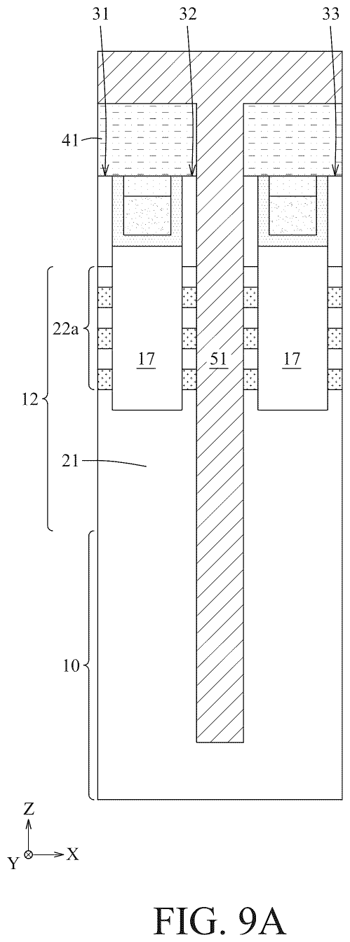

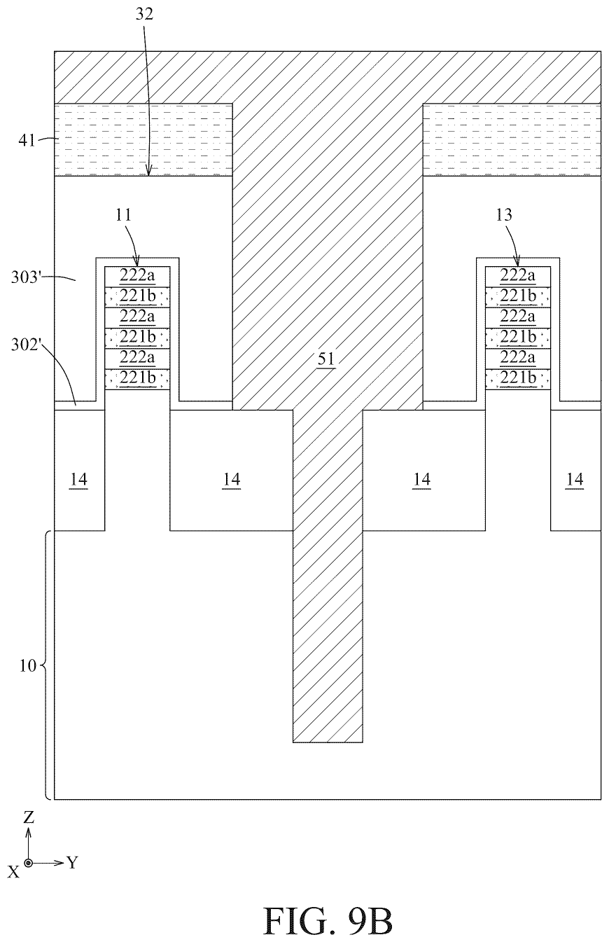

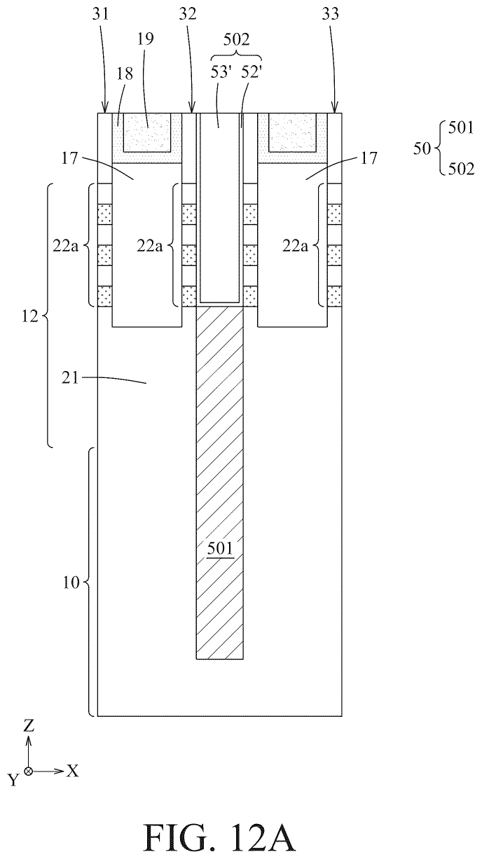

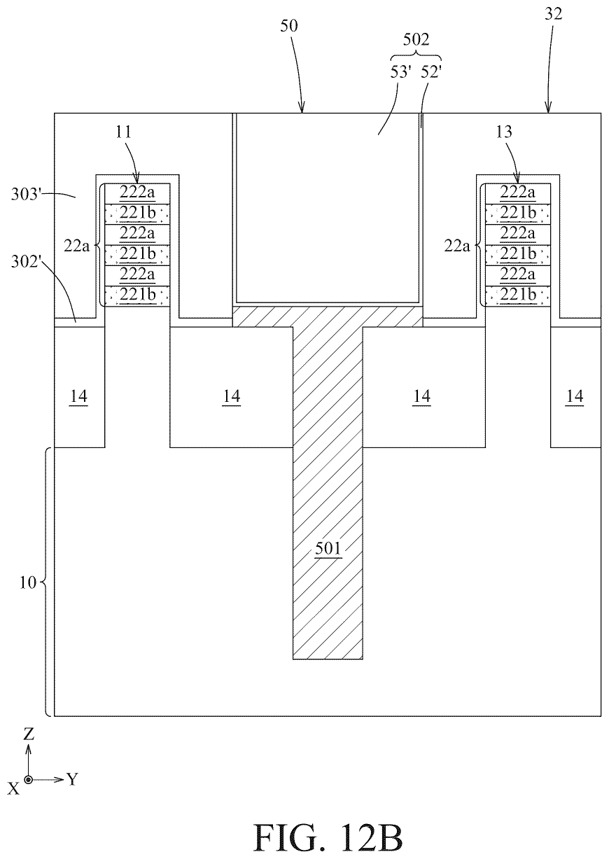

Referring to FIG. 1 and the examples illustrated in FIGS. 9A to 12B, the method 1 proceeds to step S08, where an isolation structure 50 (see FIGS. 12A and 12B) is formed in the trench 43 (see FIGS. 8A and 8B). FIGS. 12A and 12B are schematic sectional views respectively similar to those of FIGS. 8A and 8B, but illustrating the structures after step S08. FIGS. 9A-9B, 10A-10B, and 11A-11B respectively illustrate three possible intermediate states in step S08 in accordance with some embodiments.

The isolation structure 50 includes a lower portion 501 and an upper portion 502 formed on the lower portion 501. The lower portion 501 extends from the upper portion 502 into the substrate 10. In some embodiments, the lower portion 501 is in direct contact with the fin 21 of the fin structure 12 and the substrate 10. The lower portion 501 and the upper portion 502 are made of different materials. In some embodiments, the lower portion 501 includes silicon oxide, carbon-doped silicon oxide (SiOC, which may be also referred to as silicon oxycarbide), or a combination thereof. An atomic percentage of nitrogen in the lower portion 501 is less than about 1% so as to prevent negative charges from being induced in a surface region of each of the substrate 10 and the fin 21 of the fin structure 12 which faces to the lower portion 501. In some embodiments, the upper portion 502 includes silicon nitride. The upper portion 502 is configured to be separated from the fin 21 of the fin structure 12 so as to prevent negative charges from being induced in the fin 21 of the fin structure 12. In other words, an interface between the lower and upper portions 501, 502 is not lower than a level of an upper surface of the fin 21 of the fin structure 12. In some embodiments, the interface between the lower and upper portions 501, 502 is not higher than a level of upper surfaces of the stacking portions 22a of the fin structure 12 so that the upper portion 502 may have a sufficient thickness to prevent the lower portion 501 from being consumed or damaged in subsequent etching processes.

In some embodiments, step S08 may include multiple sub-steps as shown in FIGS. 9A to 12B.

First, as shown in FIGS. 9A and 9B, a solidified dielectric film 51 is formed to cover the structure shown in FIGS. 8A and 8B and fill the trench 43. The solidified dielectric film 51 includes the material of the lower portion 501. In some embodiments, formation of the solidified dielectric film 51 may include a deposition step and a curing step following the deposition step.

In some embodiments, in the deposition step, a precursor dielectric film is formed to fill the trench 43 and over the patterned hard mask 41 by a chemical reaction among a gaseous precursor material, an oxygen-containing plasma and a nitrogen-containing plasma. In some embodiments, the deposition step is performed using a flowable CVD to ensure that the precursor dielectric film is filled into the high aspect ratio trench 43 with minimized amounts of voids. The precursor dielectric film includes silicon, oxygen, nitrogen, and hydrogen, and each of an atomic percentage of nitrogen and an atomic percentage of hydrogen in the precursor dielectric film is greater than about 5%. In some other embodiments, the precursor dielectric film further includes carbon in addition to silicon, oxygen, nitrogen, and hydrogen.

To be specific, in the case that the solidified dielectric film 51 is made of silicon oxide, the gaseous precursor material may include a silicon-containing precursor, and the precursor dielectric film thus obtained includes hydrogenated silicon oxynitride (SiON: H). Alternatively, in the case that the solidified dielectric film 51 is made of carbon-doped silicon oxide, the gaseous precursor material may further include a carbon-containing precursor in addition to the silicon-containing precursor, and the precursor dielectric film thus obtained includes hydrogenated silicon oxycarbon nitride (SiOCN:H).

In some embodiments, the silicon-containing precursor may include a silylamine-based material (such as trisilylamine (TSA, (SiH₃)₃N), or the like). In some embodiments, the carbon-containing precursor may include alkane (e.g., ethane, propane, or the like), alkene (e.g., ethylene, propene, or the like), alkyne (e.g., propyne (methylacetylene), or the like), or combinations thereof. In some embodiments, the oxygen-containing plasma may include O* radicals. In some embodiments, the nitrogen-containing plasma may include NH* radicals, NH₂* radicals, N* radicals, or combinations thereof. In some embodiments, a first precursor gas for generating the oxygen-containing plasma may include oxygen gas, ozone gas, water steam or other suitable precursor gases. In some embodiments, a second precursor gas for generating the nitrogen-containing plasma may include ammonia or other suitable precursor gases. In some embodiments, the oxygen-containing plasma and the nitrogen-containing plasma are generated by a remote plasma source located outside of a reaction chamber, and then are introduced into the reaction chamber to mix with the gaseous precursor material.

In some embodiments, at the earlier stage of the chemical reaction among the gaseous precursor material, the oxygen-containing plasma and the nitrogen-containing plasma, the molecules of the precursor dielectric film have a relatively low molecular weight and have a flowable nature. Such flowable nature is beneficial to filling of the precursor dielectric film into the trench 43 with minimized voids trapped therein. During filling the trench 43 with the precursor dielectric film, the molecular weight of the molecules in the precursor dielectric film is gradually increased, and thus the flowability of the precursor dielectric film is reduced accordingly.

The reaction rate of the chemical reaction may be controlled by adjusting the flow rates of the gaseous precursor material, the first precursor gas and the second precursor gas. In some embodiments, a ratio of a flow rate of the gaseous precursor material (e.g., a sum of the silicon-containing precursor and the carbon-containing precursor) to a flow rate of a sum of the first and second precursor gases may range from about 1:1 to about 1:100. In the case that the ratio is greater than 1:1 (i.e., the flow rate of the gaseous precursor material is greater than the flow of the sum of the first and second precursor gases), the trench 43 may not be completely filled with the precursor dielectric film. In some embodiments, the reaction is performed at a temperature ranging from about 0° C. to about 200° C. In some embodiments, the reaction is performed at a pressure ranging from about 50 mtorr to about 30 torr. In some embodiments, a first carrier gas may be introduced into the reaction chamber along with the gaseous precursor material. In some embodiments, a second carrier gas may be introduced along with the first and second precursor gases so as to increase plasma generation efficiency of the oxygen-containing plasma and the nitrogen-containing plasma. Each of the first and second carrier gases includes an inert gas, such as argon gas (Ar), helium gas (He), nitrogen gas (N₂), neon gas (Ne), krypton gas (Kr), xenon gas (Xe), or the like.

After the deposition step, the curing step is performed to reduce the atomic percentage of nitrogen in the precursor dielectric film such that the precursor dielectric film is solidified to form the solidified dielectric film 51 in which the atomic percentage of nitrogen is less than about 1%. In some embodiments, the solidified dielectric film 51 is free from nitrogen (i.e., the atomic percentage of nitrogen in the solidified dielectric film 51 is zero). In some embodiments, the curing step includes exposing the precursor dielectric film to a ultra-violet (UV) light. In some embodiments, the precursor dielectric film may be cured in an environment including a diluted gas, such as Ar, He, H₂, Ne, Kr, Xe, N₂, or the like. In some embodiments, the wavelength of the UV light may range from about 100 nm to about 400 nm. In some embodiments, the curing step may be performed at a temperature ranging from about 0° C. to about 200° C.

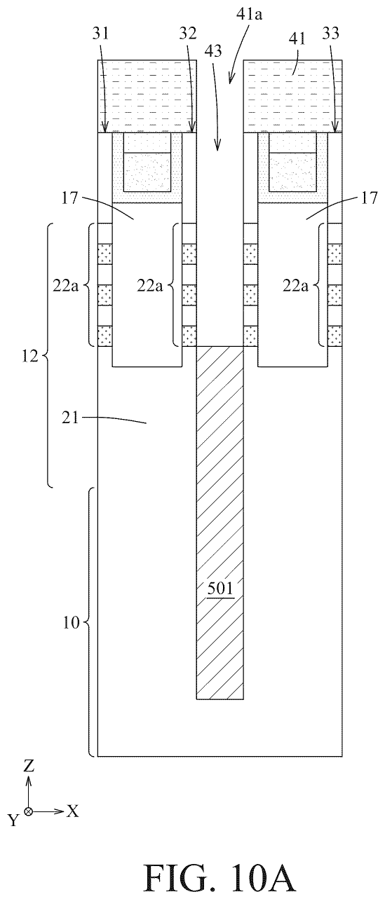

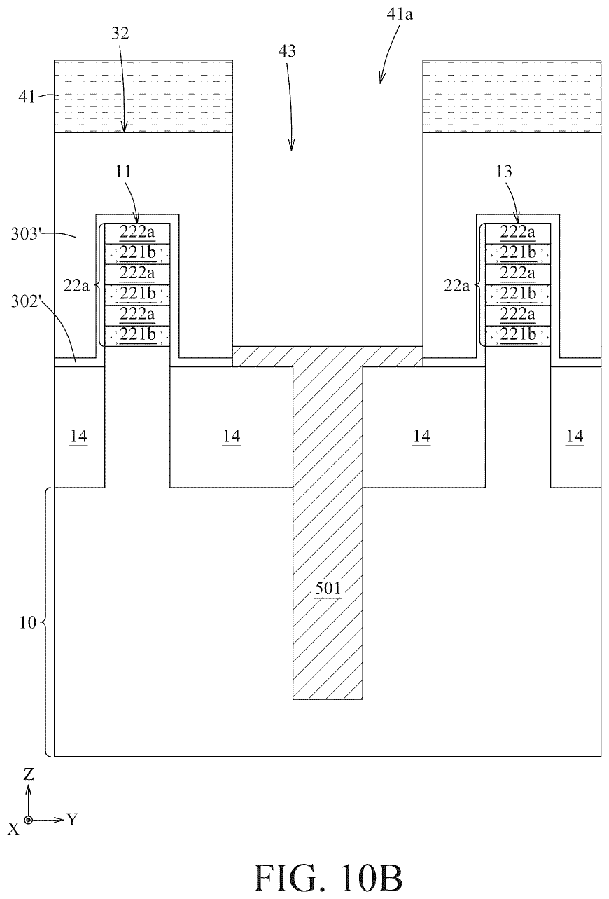

Next, as shown in FIGS. 10A and 10B, the solidified dielectric film 51 (see FIGS. 9A and 9B) is etched back by an etching process so as to obtain the lower portion 501 in a lower region of the trench 43 and expose an upper region of the trench 43, while the elements protected by the patterned hard mask 41 are substantially intact. The lower portion 501 has an upper surface that is at a level which is not lower than the level of the upper surface of the fin 21 of the fin structure 12, and which is not higher than the level of the upper surfaces of the stacking portions 22a in the fin structure 12.

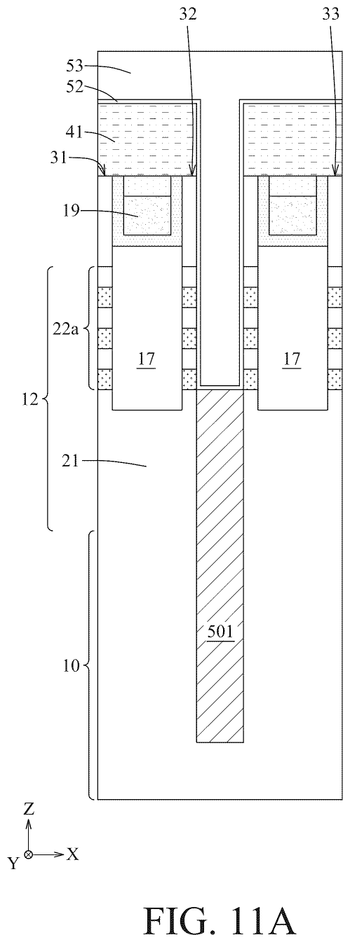

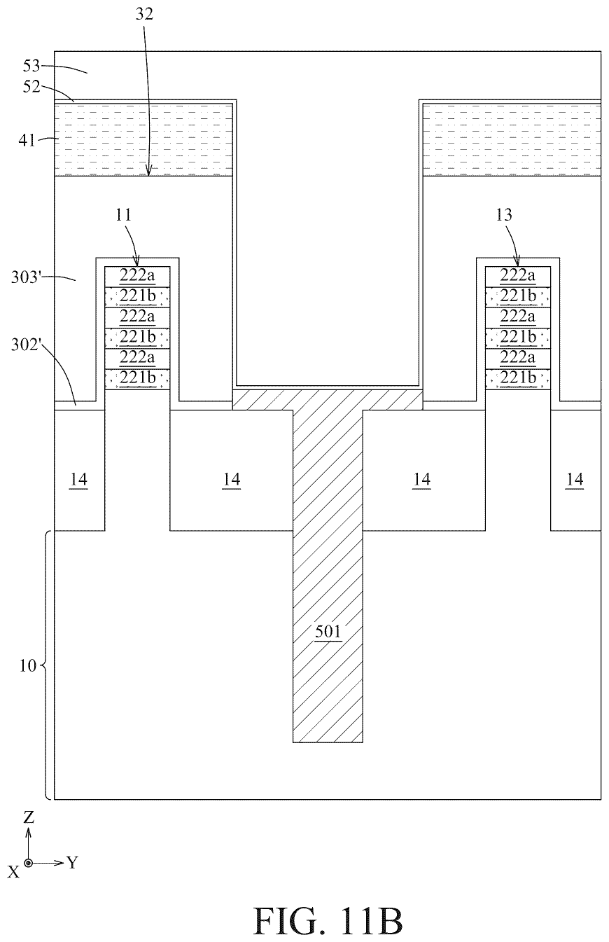

Next, as shown in FIGS. 11A and 11B, a liner 52 is conformally formed on the patterned hard mask 41 and an inner surface of the upper region of the trench 43 (see FIGS. 10A and 10B) by CVD, ALD, or other suitable deposition techniques, and a refill layer 53 is formed on the liner 52 to fill the upper region of the trench 43 by CVD, PECVD, ALD, PEALD, or other suitable deposition techniques. In some embodiments, the liner 52 is made of silicon oxide, silicon oxycarbide, or a combination thereof. The liner 52 may be used to prevent the underlying structure located therebeneath from being damage by plasma during formation of the refill layer 53. In some embodiments, a thickness of the liner 52 may range from about 1.5 nm to about 3 nm. In some embodiments, the refill layer 53 is made of silicon nitride.

Next, as shown in FIGS. 12A and 12B, a planarization process (e.g., CMP) is performed to the structure shown in FIGS. 11A and 11B to expose the ILD layer 19, thereby obtaining the upper portion 502 of the isolation structure 50. The upper portion 502 includes a treated liner 52′ and a treated refill layer 53′ which are obtained from the liner 52 and the refill layer 53, respectively.

In some other embodiments, different from the sub-steps described above with reference to FIGS. 9A and 9B, and FIGS. 10A and 10B, the lower portion 501 of the isolation structure 50 includes multiple material layers which are formed by multiple process cycles, respectively. Each of the process cycles includes a deposition step, an etching step and an oxidation step. The deposition step, the etching step and the oxidation step are performed in the same reaction chamber.

In the deposition step, a silicon-containing plasma and a first hydrogen-containing plasma are generated in the reaction chamber so as to form a silicon-based layer on the patterned hard mask 41 and an inner surface of the trench 43 (see FIGS. 8A and 8B). In some embodiments, a precursor gas for generating the silicon-containing plasma includes silanes (for example, but not limited to, silane (SiH₄), disilane (Si₂H₆), trisilane (Si₃H₈), or the like), and may be introduced into the reaction chamber with a flow rate ranging from about 10 sccm to about 50 sccm. In some embodiments, a precursor gas for generating the first hydrogen-containing plasma includes hydrogen gas (H₂), and may be introduced into the reaction chamber with a flow rate ranging from about 100 sccm to about 3000 sccm. In some embodiments, the precursor gases used in the deposition step may be ignited to form into the plasma at a plasma source power ranging from about 50 W to about 150 W. In some embodiments, the silicon-based layer is formed at a temperature ranging from about 100° C. to about 450° C. under a pressure ranging from about 0.6 torr to about 5 torr. In some embodiments, the silicon-based layer is a silicon layer. In some other embodiments, in the case that the solidified dielectric film 51 includes carbon-doped silicon oxide, the precursor gas for generating the silicon-containing plasma may include alkylsilanes (for example, but not limited to, methylsilane, ethylsilane, dimethylsilane, diethylsilane, ethyl(methyl)silane, trimethylsilane, triethylsilane, dimethyl(ethyl)silane, diethyl(methyl)silane, tetramethylsilane, tetraethylsilane, ethyl(trimethyl)silane, methyl(triethyl)silane, diethyl(dimethyl)silane, or the like). In such case, the silicon-based layer may include a silicon carbide (SiC) layer.

In the etching step, a second hydrogen-containing plasma is generated in the reaction chamber to remove a top portion of the silicon-based layer, leaving a bottom portion of the silicon-based layer at a bottom of the trench 43. In some embodiments, a precursor gas for generating the second hydrogen-containing plasma includes hydrogen gas (H₂), and may be introduced into the reaction chamber with a flow rate ranging from about 100 sccm to about 3000 sccm. In some embodiments, the precursor gas used in the etching step is ignited to form the plasma with a plasma source power ranging from about 200 W to about 300 W. In some embodiments, the silicon-based layer is etched at a temperature ranging from about 100° C. to about 450° C. under a pressure ranging from about 0.6 torr to about 10 torr. In some embodiments, the pressure at the etching step is greater than that at the deposition step.

In the oxidation step, an oxygen-containing plasma is generated in the reaction chamber to oxidize the bottom portion of the silicon-based layer so as to obtain a corresponding one of the multiple material layers. In some embodiments, a precursor gas for generating the oxygen-containing plasma includes oxygen gas, ozone gas, water steam, or the like, and may be introduced into the reaction chamber with a flow rate ranging from about 50 sccm to about 1000 sccm. In some embodiments, the precursor gas used in the oxidation step is ignited to form the plasma at a plasma source power ranging from about 50 W to about 500 W. In some embodiments, the bottom portion of the silicon-based layer is oxidized at a temperature ranging from about 100° C. to about 450° C. under a pressure ranging from about 0.6 torr to about 10 torr.

The lower portion 501 is formed in a bottom-up manner by repeating the aforesaid process cycle until the upper surface of the lower portion 501 reaches a desirable level (i.e., a level that is not lower than the level of the upper surface of the fin 21 of the fin structure 12, and not higher than the level of the upper surfaces of the stacking portions 22a in the fin structure 12).

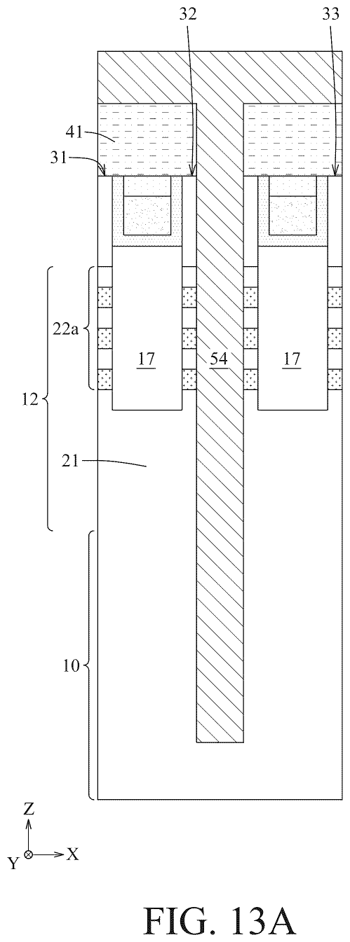

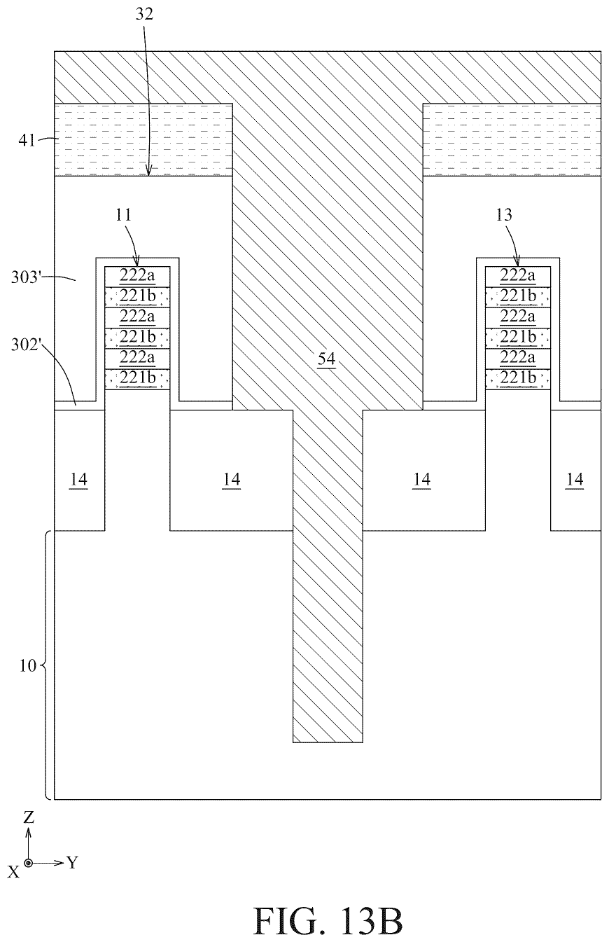

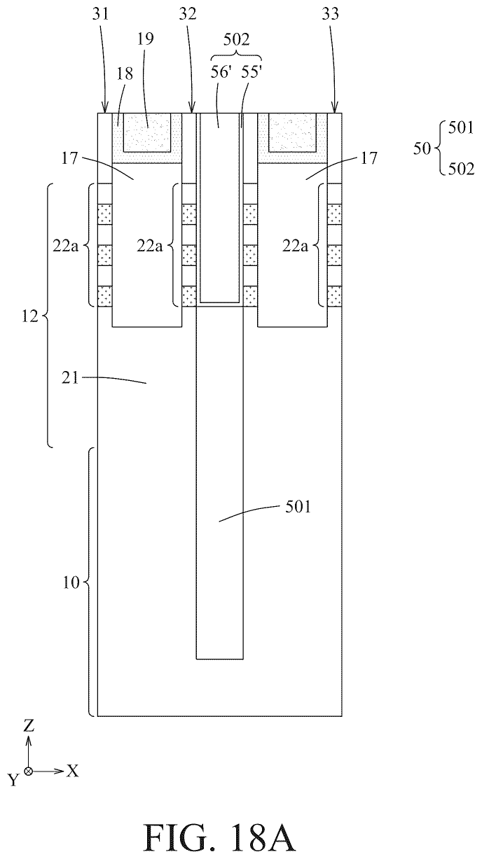

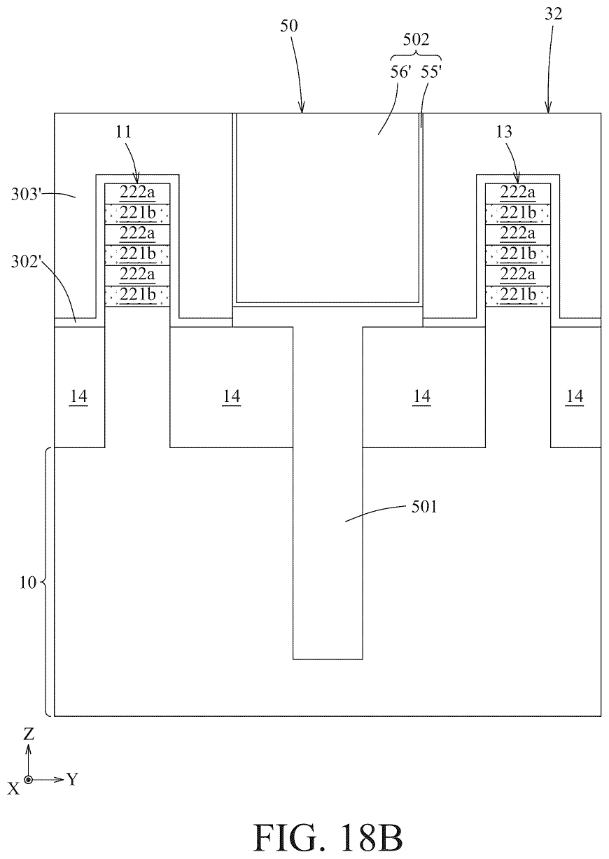

In some alternative embodiments, the isolation structure 50 is formed to have a configuration as shown in FIGS. 18A and 18B. The isolation structure 50 shown in FIGS. 18A and 18B has a configuration similar to that shown in FIGS. 12A and 12B, but the lower portion 501 is an air gap. In such case, step S08 is not performed in the sequence as described above with reference to FIGS. 9A to 12B, but includes multiple sub-steps as shown in FIGS. 13A to 18B.

First, as shown in FIGS. 13A and 13B, an amorphous carbon layer 54 is formed to cover the structure shown in FIGS. 8A and 8B and to fill the trench 43. In some embodiments, the amorphous carbon layer 54 may be formed by CVD, in which two different monomers are subjected to a polymerization process. In some embodiments, a first monomer may include di-isocyanate, ((NCO)₂R¹), and a second monomer may include diamine ((NH₂)₂R²), where R¹ and R² independently represent a hydrocarbon radical with a saturated or unsaturated, linear or branched carbon chain. For example, the first monomer may be 1, 3- or 1, 4-phenylene dimethyl diisocyanate, or the like, and the second monomer may be 1, 3-phenylene dimethyl diamine, or the like. In the polymerization process, the first monomer and the second monomer are polymerized to form the amorphous carbon layer 54. In some embodiments, the polymerization process is performed at a temperature ranging from about 50° C. to about 200° C. In some embodiments, the amorphous carbon layer 54 may be also referred to as an ashless carbon (ALC) layer.

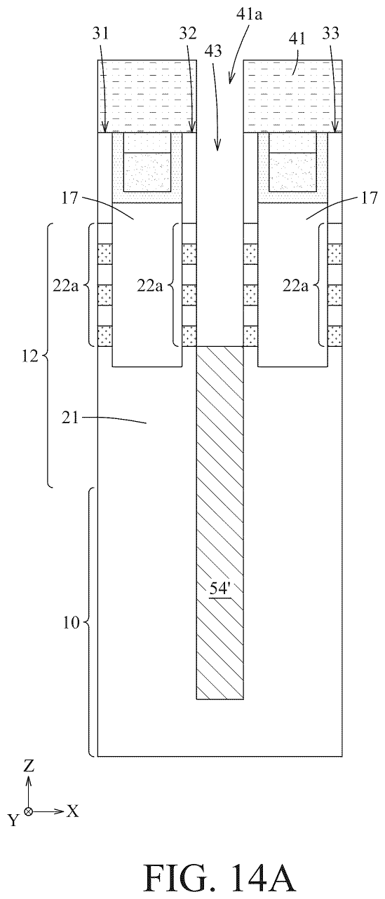

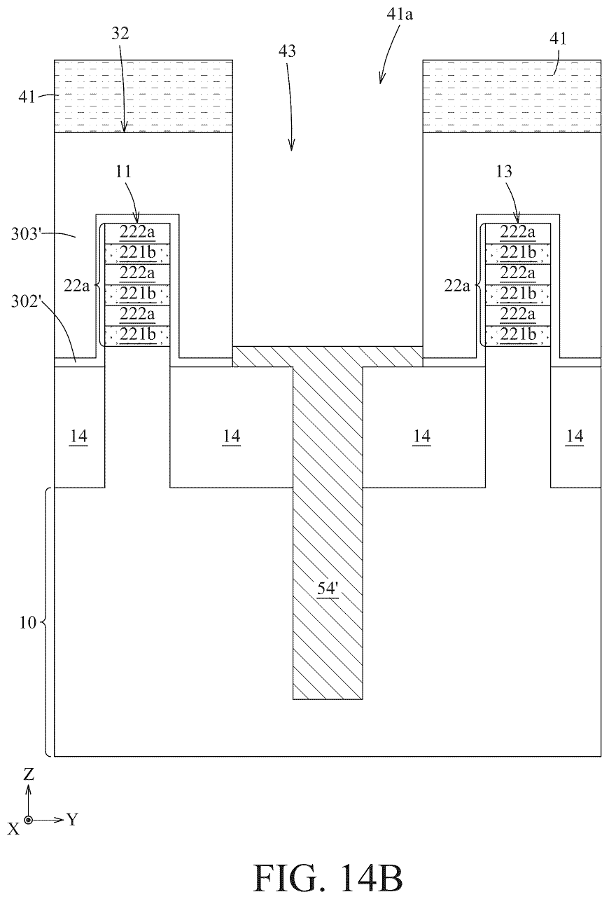

Afterwards, as shown in FIGS. 14A and 14B, a trimming process is performed to trim the amorphous carbon layer 54 so as to reduce a level of the amorphous carbon layer 54′ to be not lower than the level of the upper surface of the fin 21 of the fin structures 12 and not higher than the level of the upper surfaces of the stacking portions 22a of the fin structure 12. The level of the upper surface of the trimmed amorphous carbon layer 54′ may be controlled by the process time of the trimming process. The trimmed amorphous carbon layer 54′ is in a position corresponding to the air gap to be formed subsequently. In some embodiments, the trimming process may include a baking process performed in the presence of oxygen gas, ozone gas, water steam, or combination thereof. In some embodiments, the baking process is performed at a temperature ranging from about 200° C. to about 400° C. In some alternative embodiments, the trimming process may include a plasma etching process utilizing an oxygen-containing plasma. Other suitable trimming processes are also within the contemplated scope of the present disclosure.

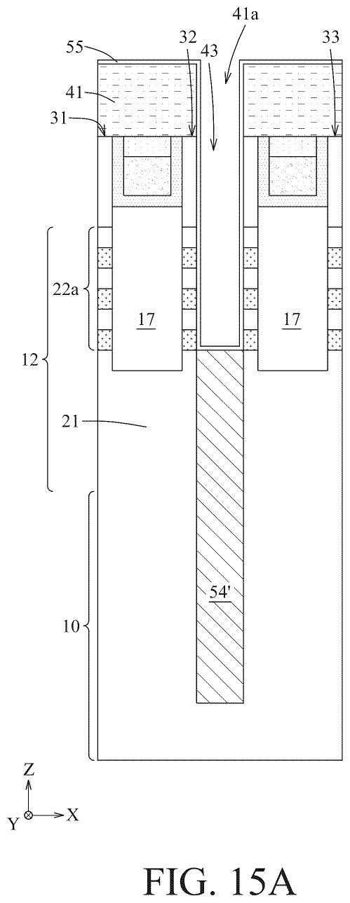

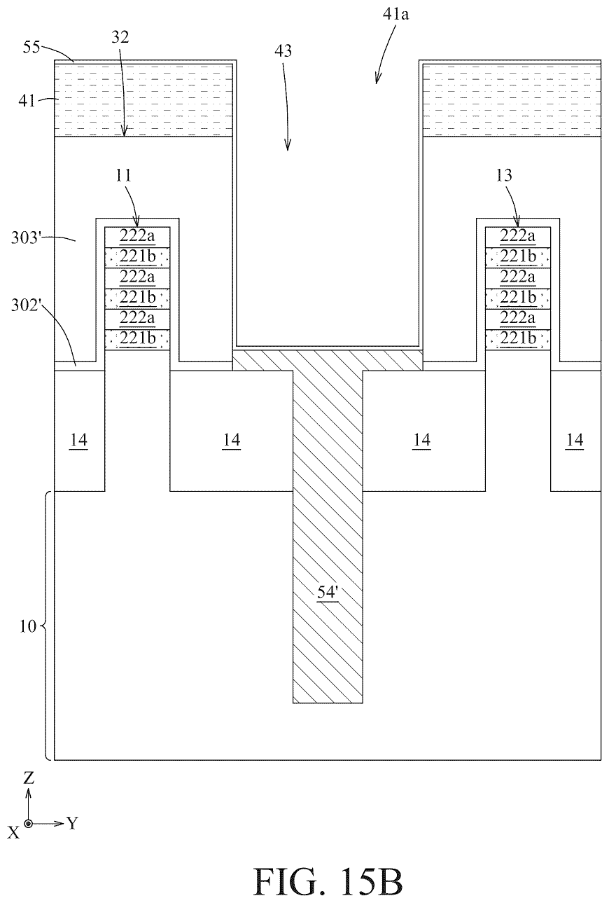

Next, as shown in FIGS. 15A and 15B, a liner 55 is conformally formed on the patterned hard mask 41 and the inner surface of the upper region of the trench 43. The liner 55 may be formed by PEALD, or other suitable deposition techniques at a relatively low temperature so that the liner 55 has a porous structure or a loose structure. As such, the trimmed amorphous carbon layer 54′ may be outgassed or released through the liner 55. In some embodiments, the liner 55 is made of silicon oxide, silicon oxycarbide, or a combination thereof. In some embodiments, a thickness of the liner 55 may range from about 1.5 nm to about 3 nm. In the case that the thickness of the liner 55 is greater than about 3 nm, the trimmed amorphous carbon layer 54′ may be not completely removed. In the case that the thickness of the liner 55 is less than about 1.5 nm, the liner 55 may be broken after removing the trimmed amorphous carbon layer 54′. In such case, a refill layer 56 to be subsequently formed may be undesirably filled into the lower region of trench 43, and results in failure to provide an air gap.

In some embodiments, the PEALD process may be performed at a temperature which is lower than the decomposition temperature (e.g., about 200° C.) of the trimmed amorphous carbon layer 54′. For example, the PEALD process may be performed at a temperature ranging from about 50° C. to about 120° C. In some embodiments, the PEALD process may be performed at a pressure ranging from about 1 torr to about 10 torr. In some embodiments, the PEALD process includes a plurality of deposition cycles. In each of the deposition cycles, a monoatomic layer of the liner 55 is deposited. Each of the deposition cycles includes a first reaction step and a second reaction step. In the first reaction step, a silicon-containing precursor gas is reacted with hydroxyl groups on the patterned hard mask 41 and the inner surface of the upper region of the trench 43 to form a precursor film thereon. In some embodiments, the silicon-containing precursor gas includes bis(diethylamino)silane (BDEAS), bis(tertiary-butylamino)silane (BTBAS), tertiary-butylaminosilane (TBAS), diethylaminosilane (DEAS), or combinations thereof. In some embodiments, in the first reaction step, the silicon-containing precursor gas is introduced in a reaction chamber for about 0.05 second to about 2 seconds, and the introduction of the silicon-containing precursor gas is stopped before proceeding to the second reaction step. In the second reaction step, an oxygen-containing plasma is generated for oxidizing the precursor film to form the monoatomic layer. In some embodiments, a reactant gas for generating the oxygen-containing plasma includes ozone gas, water steam, oxygen gas, or combinations thereof. In some embodiments, the reactant gas is introduced into the reaction chamber in a flow rate ranging from about 100 sccm to about 4000 sccm. In some embodiments, the reactant gas is continuously introduced into the reaction chamber during the first and second reaction steps, and is ignited to form the oxygen-containing plasma during the second reaction step. In some embodiments, in the second reaction step, a radio frequency (RF) power for generating the oxygen-containing plasma ranges from about 50 W to about 500 W for a time period ranging for about 0.5 seconds to about 5 seconds. In some embodiments, a carrier gas is continuously introduced into the reaction chamber during the first and second reaction steps. In some embodiments, the carrier gas includes an inert gas, such as He, Ne, Ar, Kr, Xe, N₂, or the like. The aforesaid deposition cycle may be repeatedly executed until the desirable thickness of the liner 55 is obtained.

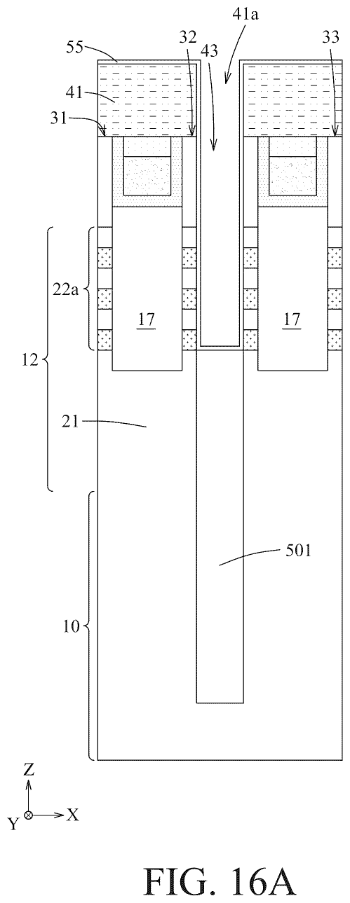

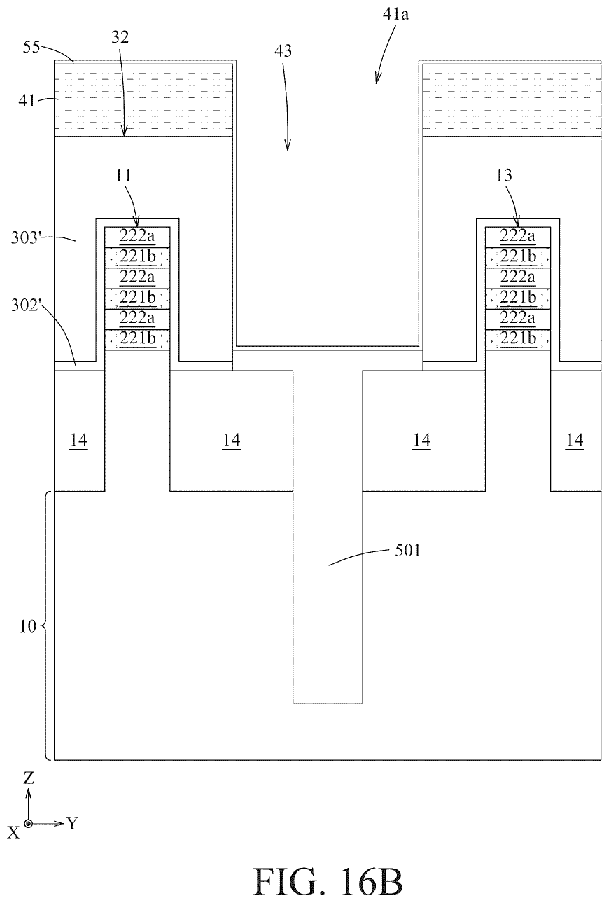

Thereafter, as shown in FIGS. 16A and 16B, a removal process is performed to remove the trimmed amorphous carbon layer 54′ (see FIGS. 15A and 15B). The removal process may include a baking process which may be similar to the baking process as described in the trimming process with reference to FIGS. 14A and 14B, but the process time of the backing process for removing the trimmed amorphous carbon layer 54′ is longer than that for trimming the amorphous carbon layer 54, and the temperature of the backing process for removing the trimmed amorphous carbon layer 54′ is higher than that for trimming the amorphous carbon layer 54. In some embodiments, the baking process for removing the trimmed amorphous carbon layer 54′ is performed at a temperature ranging from about 200° C. to about 400° C., or greater than about 400° C. so as to ensure the trimmed amorphous carbon layer 54′ to be removed completely.

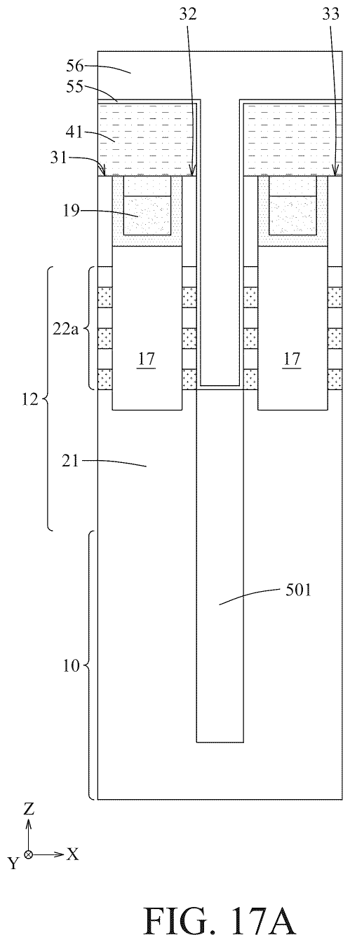

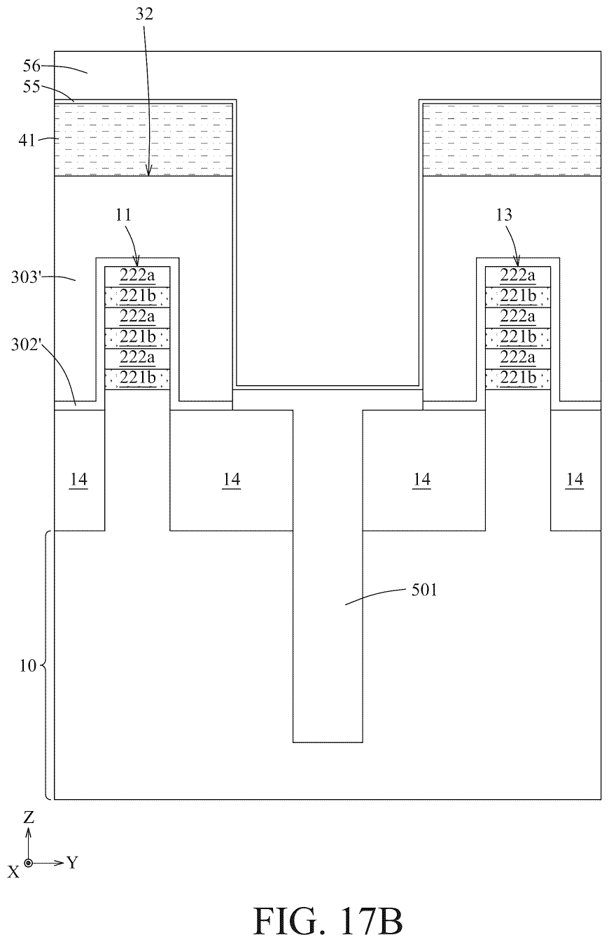

Then, as shown in FIGS. 17A and 17B, a refill layer 56 is formed on the liner 55 to fill the upper region of the trench 43 (see FIGS. 16A and 16B) by CVD, PECVD, ALD, PEALD, or other suitable deposition techniques. In some embodiments, the refill layer 56 is made of silicon nitride.

Subsequently, as shown in FIGS. 18A and 18B, a planarization process (e.g., CMP) is performed to the structure shown in FIGS. 17A and 17B to expose the ILD layer 19, thereby obtaining the upper portion 502 of the isolation structure 50. The upper portion 502 includes a treated liner 55′ and a treated refill layer 56′ which are obtained from the liner 55 and the refill layer 56, respectively.

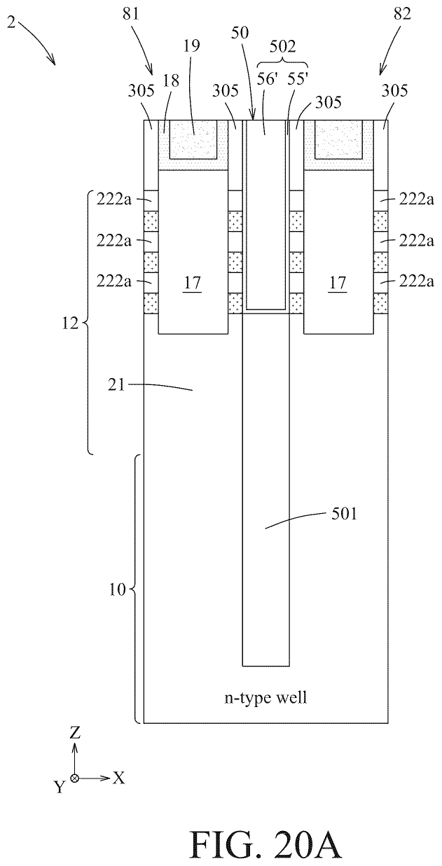

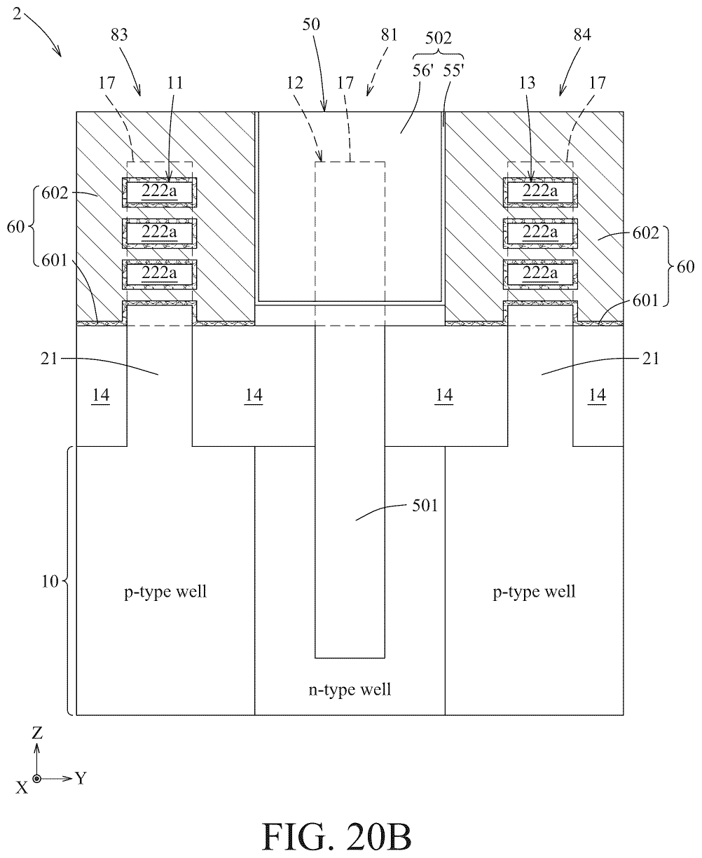

Referring to FIG. 1 and the examples illustrated in FIGS. 19A, 19B, 20A, and 20B, the method 1 proceeds to step S09, where a replacement gate process is performed, thereby obtaining the semiconductor structure 2 including multiple semiconductor devices (e.g., 81, 82, 83, 84). FIGS. 19A and 19B are schematic sectional views similar to those of FIGS. 12A and 12B, but illustrating the structures after step S09. FIGS. 20A and 20B are schematic sectional views similar to those of FIGS. 19A and 19B, but the lower portion 501 is the air gap. In other words, FIGS. 20A and 20B are schematic sectional views similar to those of FIGS. 18A and 18B, but illustrating the structures after step S09.

After the gate replacement process, the second films 222a of the stacking portions 22a of the fin structures 11, 12, 13 (see FIGS. 12A, 12B, 18A, and 18B) remain to serve as multiple stacks of channel films (also denoted by 222a), and multiple gate structures 60 (two of which is shown in FIG. 19B or 20B) formed around the multiple stacks of channel films 222a, respectively. Each of the semiconductor devices 81, 82, 83, 84 is partially shown in FIGS. 19A and 19B. As shown in FIG. 19A or 20A, the semiconductor device 81 is disposed on a first part of the fin 21 of the fin structure 12, and the semiconductor device 82 is disposed on a second part of the fin 21 of the fin structure 12 and is separated from the semiconductor device 81 by the isolation structure 50. Each of the semiconductor devices 81, 82 includes two source/drain portions 17 (one of which is shown in FIG. 19A or 20A), a corresponding stack of the channel films 222a (each channel film 222a interconnecting the two source/drain portions 17), and a corresponding one of the gate structures 60 (not shown in FIG. 19A or 20A). Each of the semiconductor devices 81, 82 may be controlled by the corresponding gate structure 60. Other semiconductor devices (e.g., 83, 84 and others not shown in figures) may have similar configurations. As shown in FIG. 19B, the semiconductor device 83 is disposed on the fin 21 of the fin structure 11, and the semiconductor device 84 is disposed on the fin 21 of the fin structure 13. The semiconductor devices 83, 84 are separated from each other by the isolation structure 50 and the ILD layer 19 (not shown in FIG. 19B or 20B).

In some embodiments, the semiconductor devices 81, 82 are n-FETs, and the semiconductor devices 83, 84 are p-FETs. In such case, a p-type well is formed in the fin 21 of the fin structure 12 and a first portion of the substrate 10 located immediately beneath the fin 21 of the fin structure 12, and an n-type well is formed in the fins 21 of the fin structures 11, 13 and second portions of the substrate 10 located immediately beneath the fins 21 of the fin structures 11, 13, respectively.

It is worth noting that, with the provision of the isolation structure 50 including the nitrogen-free lower portion 501, negative charges (which are likely to be induced by the defects occurring during formation of the nitrogen-based dielectric material) may be prevented from being induced in the fin 21 of the fin structure 11. Hence, an inversion of conductivity type by the negative charged may be prevented (i.e., the fin 21 of the fin structure 11 and the first portion of the substrate 10 may still have the p-type conductivity and may be prevented from being inverted to the n-type conductivity since the negative charges are absent. As such, when the p-FET 83 (or 84) is set at an on-state and the n-FET 81 (or 82) is set at an off-state, a current will not be detected from the n-FET 81 (or 82) because the n-FET 81 (or 82) is well electrically isolated by the p-type well. Furthermore, when the n-FET 81 is set at an on-state and the n-FET 82 is set at an off-state, a current will not be detected from the n-FET 82 owing to the absence of the negative charges induced in the fin 21 of the fin structure 12 and the first portion of the substrate 10. That is, any one of the semiconductor devices 81, 82, 83, or 84 can be indeed set at an off-state when no voltage is applied thereto.

In the replacement gate process, the patterned dummy gate 303′ and the patterned dummy dielectric 302′ in each of the dummy structures 31, 32, 33 (only the patterned dummy gate 303′ and the patterned dummy dielectric 302′ of the dummy gate structure 32 are shown in FIGS. 12B or FIG. 18B) are removed to expose the stacking portions 22a of the fin structures 11, 12, 13. Then, the etched first films 221b of the stacking portions 22a of the fin structures 11, 12, 13 (which are not removed during formation of the isolation structure 50 as shown in FIG. 12B or 18B) are selectively removed, while the second films 222a (i.e., the channel films) in the fin structures 11, 12, 13 are substantially intact. Afterwards, the gate structures 60 are each formed to surround the corresponding stack of the channel films 222a.

In some embodiments, each of the gate structures 60 includes a gate dielectric 601 and a gate electrode 602. The gate electrode 602 is separated from the corresponding stack of the channel films 222a by the gate dielectric 601. The gate electrode 602 may include a work function metal. In some embodiments, the gate dielectric 601 includes a metal-containing high-k dielectric layer. The metal-containing high-k dielectric layer includes, for example, but not limited to, Hf-containing dielectric oxide materials, Ta-containing dielectric oxide materials (e.g., Ta₂O₅), Ti-containing dielectric oxide materials, Zr-containing dielectric oxide materials, Al-containing dielectric oxide materials (e.g., Al₂O₃), La-containing dielectric materials, other suitable materials (having a dielectric constant not less than about 9 or larger than about 13), or combinations thereof. The materials (e.g. an electrically conductive material and the work function metal material) of the gate electrode 602 may include, for example, but not limited to, a metal (e.g., copper, aluminum, titanium, tantalum, cobalt, tungsten, or the like, or alloys thereof), polysilicon, metal-containing nitrides (e.g., TaN), metal-containing silicides (e.g., NiSi), metal-containing carbides (e.g., TaC), or the like, or combinations thereof. Other suitable materials for forming the gate dielectric 601 and the gate electrode 602 are within the contemplated scope of the present disclosure.

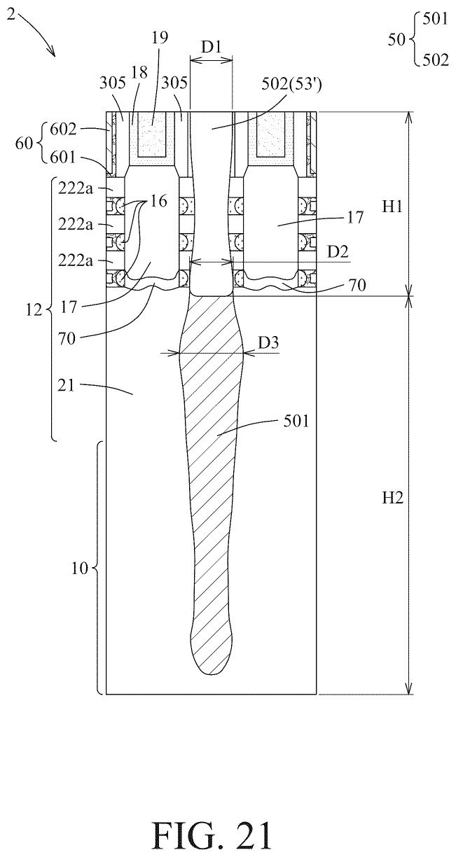

FIG. 21 is a schematic sectional view similar to that of FIG. 19A, but illustrating a contour of the isolation structure 50 in more detail. In some embodiments, the semiconductor structure 2 further includes dielectric portions 70 which are respectively disposed beneath the source/drain portions 17.

In some embodiments, as shown in FIG. 21, the treated liner 52′ shown in FIG. 19A is omitted (i.e., the isolation structure 50 may include the treated refill layer 53′ only). In some embodiments, as shown in FIG. 21, the isolation structure 50 have an upper dimension (D1), a middle dimension (D2) and a lower dimension (D3), all defined in the X direction. The upper dimension (D1) is a width of an upper surface of the upper portion 502 which is coplanar with an upper surface of the semiconductor structure 2 obtained after the replacement gate process. In some embodiments, the upper dimension (D1) may range from about 9 nm to about 13 nm. The middle dimension (D2) is a width of a lower part of the upper portion 502 which is close to the interface between the upper and lower portions 502, 501. The middle dimension (D2) may be substantially equal to or smaller than the upper dimension (D1). In some embodiments, the middle dimension (D2) ranges from about 7 nm to about 13 nm. The lower dimension (D3) is the maximum width of the lower portion 501. In some embodiments, the lower dimension (D3) may range from about 7 nn to about 15 nm.

In some embodiments, the upper portion 502 has a height (H1) in the Z direction ranging from about 55 nm to about 75 nm. In some embodiments, the lower portion 501 has a height (H2) in the Z direction that is greater than the height (H1) of the upper portion 502. In some embodiments, the height (H2) of the lower portion 501 ranges from about 100 nm to about 150 nm.

Possible materials suitable for the dielectric portions 70 are similar to those for the inner spacers 16, and thus the details thereof are omitted for the sake of brevity. The dielectric portions 70 are respectively disposed beneath the source/drain portions 17 of the semiconductor devices. The dielectric portions 70 may be formed by CVD, ALD, or other suitable deposition techniques, after formation of the inner spacers 16 and before formation of the source/drain portions 17.

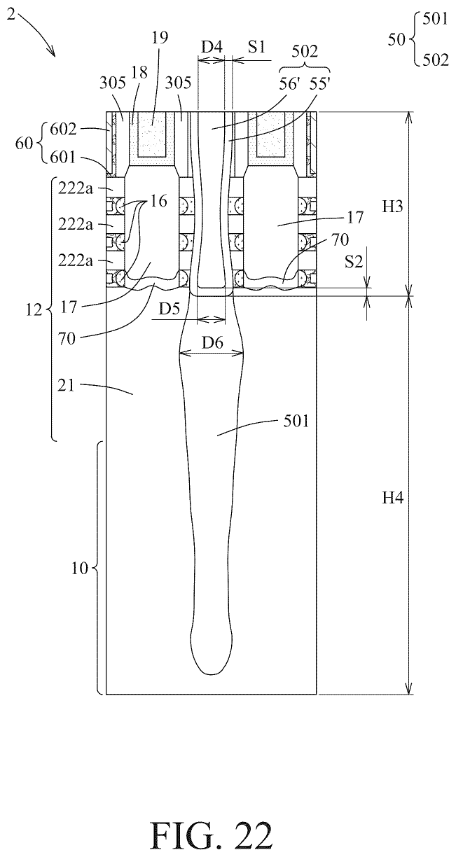

FIG. 22 is a schematic sectional view similar to that of FIG. 20A, but illustrating a contour of the isolation structure 50 in more detail

In some embodiments, the treated liner 55′ has a bottom region disposed beneath the treated refill layer 56′ and a surrounding region extending upwardly from a periphery of the bottom region to surround the treated refill layer 56′. In some embodiments, the surrounding region may have a thickness (S1) ranging from about 1 nm to about 3 nm. In some embodiments, the bottom region may have a thickness (S2) ranging from about 1 nm to about 3 nm. In some embodiments, the treated liner 55′ may have a uniform thickness. That is, the thickness of the surrounding region and the thickness of the bottom region are substantially the same.

In some embodiments, an upper surface of the treated refill layer 56′, which is coplanar with the upper surface of the semiconductor structure 2 obtained after the replacement gate process, has a width (D4) in the X direction ranging from about 3 nm to about 11 nm. In some embodiments, a width (D5) of a lower surface of the treated refill layer 56′ which is close to the interface between the upper portion and the air gap 501 ranges from about 1 to about 11 nm. The maximum width (D6) of the air gap 501 may range from about 7 nm to about 15 nm.

In some embodiments, the treated refill layer 56′ has a height (H3) in the Z direction ranging from about 55 nm to about 75 nm. In some embodiments, the air gap 501 has a height (H4) in the Z direction that is greater than the height (H3) of the treated refill layer 56′. In some embodiments, the height (H4) of the air gap 501 ranges from about 97 nm to about 149 nm.

In summary, with the provision of the isolation structure 50 including the nitrogen-free lower portion 501, negative charges, which are likely to be induced by the defects occurring during formation of the nitrogen-based dielectric material, may be prevented from being induced in the fin 21 of each of the fin structures 11, 12, 13 and the substrate 10. Thus, a body leakage current resulting from the induced negative charges may be mitigated. For example, when the semiconductor device 81 is applied with a voltage that is greater than the threshold voltage thereof such that the semiconductor device 81 is in an on-state while the semiconductor devices 82, 83, 84 are not applied with a voltage, a current will not be detected from the semiconductor devices 82, 83, 84 due to the absence of the body leakage current. That is, the semiconductor devices 82, 83, 84 are indeed in an off-state when no voltage is applied thereon. Therefore, the method for manufacturing the semiconductor structure 2 of the present disclosure has improved product yield, and the semiconductor structure 2 including the isolation structure 50 manufactured by the method has improved reliability.

In accordance with some embodiments of the present disclosure, a method for manufacturing a semiconductor structure includes: forming a fin structure on a substrate; forming two trench isolations on the substrate such that the two trench isolations are formed at two opposite sides of the fin structure; forming dummy structures over the fin structure and the two trench isolations so that the fin structure has exposed portions which are exposed from the dummy structures, and which are disposed to alternate with the dummy structures, each of the dummy structures including a dummy gate; forming source/drain portions respectively in the exposed portions of the fin structure; forming a trench which penetrates through the dummy gate of a selected one of the dummy structures and through the fin structure to terminate at the substrate; and forming an isolation structure in the trench, the isolation structure including an upper portion and a lower portion which extends from the upper portion into the substrate, the upper portion and the lower portion being made of different materials, an atomic percentage of nitrogen in the lower portion being less than 1%.

In accordance with some embodiments of the present disclosure, the lower portion includes an air gap, silicon oxide, or carbon-doped silicon oxide, and the upper portion includes silicon nitride.

In accordance with some embodiments of the present disclosure, formation of the lower portion includes forming the lower portion in the trench such that an upper surface of the lower portion is at a level which is not lower than a level of upper surfaces of the trench isolations and which is not higher than an upper surface of the fin structure, and forming the upper portion on the lower portion to fill the trench.

In accordance with some embodiments of the present disclosure, the upper portion is formed after formation of the lower portion.

In accordance with some embodiments of the present disclosure, formation of the lower portion includes forming a precursor dielectric film to fill in the trench, the precursor dielectric film including silicon, oxygen, nitrogen, and hydrogen, each of an atomic percentage of nitrogen and an atomic percentage of hydrogen in the precursor dielectric film being greater than 5%, performing a curing process on the precursor dielectric film so as to obtain a solidified dielectric film in which each of the atomic percentage of nitrogen and the atomic percentage of hydrogen is less than 1%, and etching back the solidified dielectric film so as to obtain the lower portion.

In accordance with some embodiments of the present disclosure, the precursor dielectric film is formed by a chemical reaction among a gaseous precursor material, a nitrogen-containing plasma and an oxygen-containing plasma, the gaseous precursor material including a silicon-containing precursor.

In accordance with some embodiments of the present disclosure, the lower portion is carbon-doped silicon oxide, and the gaseous precursor material further includes a carbon-containing precursor.

In accordance with some embodiments of the present disclosure, the lower portion includes multiple material layers which are formed by multiple process cycles, respectively. Each of the process cycles includes applying a silicon-containing plasma and a first hydrogen-containing plasma to the trench under a first pressure so as to form a silicon-based layer along an inner surface of the trench, applying a second hydrogen-containing plasma under a second pressure to partially remove the silicon-based layer so as to leave a bottom portion of the silicon-based layer at a bottom of the trench, and applying an oxygen-containing plasma to oxidize the bottom portion of the silicon-based layer so as to form a corresponding one of the multiple material layers.

In accordance with some embodiments of the present disclosure, the second pressure is greater than the first pressure.

In accordance with some embodiments of the present disclosure, formation of the upper portion includes forming a liner on the lower portion along an inner surface of the trench, and forming a refill layer on the liner to fill the trench.

In accordance with some embodiments of the present disclosure, the liner includes silicon oxide, carbon-doped silicon oxide, or a combination thereof, and the refill layer includes silicon nitride.

In accordance with some embodiments of the present disclosure, a method for manufacturing a semiconductor structure includes: forming a fin structure on a substrate, the fin structure including a fin and a stack disposed on the fin, the stack including first layers and second layers that are disposed to alternate with the first layers, the first layers being made of a first semiconductor material, the second layers being made of a second semiconductor material that is different from the first semiconductor material; forming dummy structures over the fin structure so that the fin structure has exposed portions which are exposed from the dummy structures and which are disposed to alternate with the dummy structures, each of the dummy structures including a dummy gate; forming source/drain portions respectively in the exposed portions of the fin structure so that the stack is patterned into stacking portions which are respectively located beneath the dummy gates; forming a trench which penetrates through the dummy gate of a selected one of the dummy structures, through a corresponding lower one of the stacking portions and through the fin to terminate at the substrate; and forming an isolation structure in the trench, the isolation structure including an upper portion and a lower portion which extends from the upper portion into the substrate, the upper portion and the lower portion being made of different materials, an atomic percentage of nitrogen in the lower portion being less than 1%.

In accordance with some embodiments of the present disclosure, the lower portion is an air gap, and the upper portion includes a liner configured to seal the air gap and a refill layer formed on the liner. The liner and the refill layer are made of different materials.

In accordance with some embodiments of the present disclosure, the liner includes silicon oxide, carbon-doped silicon oxide, or a combination thereof, and the refill layer includes silicon nitride.

In accordance with some embodiments of the present disclosure, formation of the isolation structure includes forming an amorphous carbon layer to fill the trench, trimming the amorphous carbon layer such that an upper surface of a trimmed amorphous carbon layer is at a level which is not lower than a level of an upper surface of the fin and which is not higher than a level of upper surfaces of the stacking portions, forming the liner to cover the trimmed amorphous carbon layer, after formation of the liner, removing the trimmed amorphous carbon layer to form the air gap beneath the liner, and after formation of the air gap, forming the refill layer on the liner to fill the trench.

In accordance with some embodiments of the present disclosure, the air gap is in direct contact with the fin and the substrate.

In accordance with some embodiments of the present disclosure, the upper portion is separated from the fin.

In accordance with some embodiments of the present disclosure, a semiconductor structure includes: a substrate; a fin disposed on the substrate; a first transistor disposed on a first part of the fin, and including a first source/drain portion; a second transistor disposed on a second part of the fin, and including a second source/drain; and an isolation structure disposed between the first transistor and the second transistor, and including a lower portion formed in the fin and the substrate, and an upper portion formed on the lower portion and between the first source/drain portion and the second source/drain portion, the upper portion and the lower portion being made of different materials, an atomic percentage of nitrogen in the lower portion being less than 1%.

In accordance with some embodiments of the present disclosure, the lower portion includes an air gap, silicon oxide, or carbon-doped silicon oxide, and the upper portion includes silicon nitride.

In accordance with some embodiments of the present disclosure, the upper portion is separated from the fin.

In accordance with some embodiments of the present disclosure, a method for manufacturing a semiconductor structure includes: forming a fin structure on a substrate, the fin structure including a fin and a stack disposed on the fin, the stack including first layers and second layers that are disposed to alternate with the first layers, the first layers being made of a first semiconductor material, the second layers being made of a second semiconductor material that is different from the first semiconductor material; forming two trench isolations on the substrate and at two opposite sides of the fin structure; forming dummy structures over the fin structure and the two trench isolations so that the fin structure has exposed portions which are disposed to alternate with the dummy structures, each of the dummy structures including a dummy gate; forming source/drain portions respectively in the exposed portions of the fin structure so that the stack is patterned into stacking portions which are respectively located beneath the dummy structures; forming a trench which penetrates through the dummy gate of a selected one of the dummy structures, through a corresponding lower one of the stacking portions and through the fin to terminate at the substrate; and forming an isolation structure in the trench, the isolation structure including an upper portion and a lower portion which extends from the upper portion into the substrate, the upper portion and the lower portion being made of different materials, an atomic percentage of nitrogen in the lower portion being less than 1%.

In accordance with some embodiments of the present disclosure, the lower portion includes an air gap, silicon oxide, or carbon-doped silicon oxide, and the upper portion includes silicon nitride.

In accordance with some embodiments of the present disclosure, an interface between the upper portion and the lower portion is located above a level of lower surfaces of the stacking portions and lower than a level of upper surfaces of the stacking portions.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a fin structure on a substrate;
forming two trench isolations on the substrate such that the two trench isolations are formed at two opposite sides of the fin structure;
forming dummy structures over the fin structure and the two trench isolations so that the fin structure has exposed portions which are exposed from the dummy structures, and which are disposed to alternate with the dummy structures, each of the dummy structures including a dummy gate;
forming source/drain portions respectively in the exposed portions of the fin structure;
forming a trench which penetrates through the dummy gate of a selected one of the dummy structures and through the fin structure to terminate at the substrate; and
forming an isolation structure in the trench, the isolation structure including an upper portion and a lower portion which extends from the upper portion into the substrate, the upper portion and the lower portion being made of different materials, an atomic percentage of nitrogen in the lower portion being less than 1%.

2. The method as claimed in claim 1, wherein the lower portion includes an air gap, silicon oxide, or carbon-doped silicon oxide, and the upper portion includes silicon nitride.

3. The method as claimed in claim 1, wherein formation of the lower portion includes
forming the lower portion in the trench such that an upper surface of the lower portion is at a level which is not lower than a level of upper surfaces of the trench isolations and which is not higher than an upper surface of the fin structure, and
forming the upper portion on the lower portion to fill the trench.

4. The method as claimed in claim 3, wherein the upper portion is formed after formation of the lower portion.

5. The method as claimed in claim 4, wherein formation of the lower portion includes
forming a precursor dielectric film to fill in the trench, the precursor dielectric film including silicon, oxygen, nitrogen, and hydrogen, each of an atomic percentage of nitrogen and an atomic percentage of hydrogen in the precursor dielectric film being greater than 5%,
performing a curing process on the precursor dielectric film so as to obtain a solidified dielectric film in which each of the atomic percentage of nitrogen and the atomic percentage of hydrogen is less than 1%, and
etching back the solidified dielectric film so as to obtain the lower portion.

6. The method as claimed in claim 5, wherein the precursor dielectric film is formed by a chemical reaction among a gaseous precursor material, a nitrogen-containing plasma and an oxygen-containing plasma, the gaseous precursor material including a silicon-containing precursor.

7. The method as claimed in claim 6, wherein the lower portion is carbon-doped silicon oxide, and the gaseous precursor material further includes a carbon-containing precursor.

8. The method as claimed in claim 4, wherein
the lower portion includes multiple material layers which are formed by multiple process cycles, respectively, each of the process cycles including
applying a silicon-containing plasma and a first hydrogen-containing plasma to the trench under a first pressure so as to form a silicon-based layer along an inner surface of the trench,
applying a second hydrogen-containing plasma under a second pressure to partially remove the silicon-based layer so as to leave a bottom portion of the silicon-based layer at a bottom of the trench, and
applying an oxygen-containing plasma to oxidize the bottom portion of the silicon-based layer so as to form a corresponding one of the multiple material layers.

9. The method as claimed in claim 8, wherein the second pressure is greater than the first pressure.

10. The method as claimed in claim 4, wherein formation of the upper portion includes
forming a liner on the lower portion along an inner surface of the trench, and
forming a refill layer on the liner to fill the trench.

11. The method as claimed in claim 10, wherein the liner includes silicon oxide, carbon-doped silicon oxide, or a combination thereof, and the refill layer includes silicon nitride.

12. A method for manufacturing a semiconductor structure, comprising:
forming a fin structure on a substrate, the fin structure including a fin and a stack disposed on the fin, the stack including first layers and second layers that are disposed to alternate with the first layers, the first layers being made of a first semiconductor material, the second layers being made of a second semiconductor material that is different from the first semiconductor material;
forming dummy structures over the fin structure so that the fin structure has exposed portions which are exposed from the dummy structures and which are disposed to alternate with the dummy structures, each of the dummy structures including a dummy gate;
forming source/drain portions respectively in the exposed portions of the fin structure so that the stack is patterned into stacking portions which are respectively located beneath the dummy gates;
forming a trench which penetrates through the dummy gate of a selected one of the dummy structures, through a corresponding lower one of the stacking portions and through the fin to terminate at the substrate; and
forming an isolation structure in the trench, the isolation structure including an upper portion and a lower portion which extends from the upper portion into the substrate, the upper portion and the lower portion being made of different materials, an atomic percentage of nitrogen in the lower portion being less than 1%.

13. The method as claimed in claim 12, wherein the lower portion is an air gap, and the upper portion includes a liner configured to seal the air gap and a refill layer formed on the liner, the liner and the refill layer being made of different materials.

14. The method as claimed in claim 13, wherein the liner includes silicon oxide, carbon-doped silicon oxide, or a combination thereof, and the refill layer includes silicon nitride.

15. The method as claimed in claim 14, wherein formation of the isolation structure includes
forming an amorphous carbon layer to fill the trench,
trimming the amorphous carbon layer such that an upper surface of a trimmed amorphous carbon layer is at a level which is not lower than a level of an upper surface of the fin and which is not higher than a level of upper surfaces of the stacking portions,
forming the liner to cover the trimmed amorphous carbon layer,
after formation of the liner, removing the trimmed amorphous carbon layer to form the air gap beneath the liner, and
after formation of the air gap, forming the refill layer on the liner to fill the trench.

16. The method as claimed in claim 13, wherein the air gap is in direct contact with the fin and the substrate.

17. The method as claimed in claim 13, wherein the upper portion is separated from the fin.

18. A semiconductor structure, comprising:
a substrate;
a fin disposed on the substrate;
a first transistor disposed on a first part of the fin, and including a first source/drain portion;
a second transistor disposed on a second part of the fin, and including a second source/drain; and
an isolation structure disposed between the first transistor and the second transistor, and including a lower portion formed in the fin and the substrate, and an upper portion formed on the lower portion and between the first source/drain portion and the second source/drain portion, the upper portion and the lower portion being made of different materials, an atomic percentage of nitrogen in the lower portion being less than 1%.

19. The semiconductor structure as claimed in claim 18, wherein the lower portion includes an air gap, silicon oxide, or carbon-doped silicon oxide, and the upper portion includes silicon nitride.

20. The semiconductor structure as claimed in claim 19, wherein the upper portion is separated from the fin.
